(19) United States
(12) Patent Application Publication
(10) Pub. No.: US 2022/0078920 A1
(43) Pub. Date: Mar. 10, 2022

(54) GLASS SUBSTRATES WITH BLIND VIAS HAVING DEPTH UNIFORMITY AND METHODS FOR FORMING THE SAME

(71) Applicant: CORNING INCORPORATED, Corning, NY (US)

(72) Inventors: Tian Huang, San Jose, CA (US); Yuhui Jin, Painted Post, NY (US); Ekaterina Aleksandrovna Kuksenkova, Painted Post, NY (US); Heather Nicole Vanselous, Corning, NY (US)

(21) Appl. No.: 17/468,063

(22) Filed: Sep. 7, 2021

Related U.S. Application Data
(60) Provisional application No. 63/075,871, filed on Sep. 9, 2020.

(51) Int. Cl. H05K 3/40; H05K 3/00; H05K 1/03; H05K 1/11; B23K 26/55; B23K 26/00; B23K 26/06

(52) U.S. Cl. CPC H05K 3/4038; H05K 3/0047; H05K 1/0306; H05K 1/115; B23K 2103/54; B23K 26/0006; B23K 26/0665; H05K 2201/09509; H05K 2203/107; B23K 26/55

(57) ABSTRACT

A substrate comprising: (i) a first series of blind vias into a thickness of a substrate and open to a first primary surface; and (ii) a second series of blind vias into the thickness of a substrate and open to a second primary surface. Each blind via includes an interior wall. The interior wall includes a first tapered region and a second tapered region. The first tapered region and the second tapered region have a distinct slope. Each of the blind vias of the second series of blind vias is coaxial with a different blind via of the first series of blind vias. Each blind via of the first series of blind vias has a depth that deviates from a mean depth by less than +/−10%. Each blind via of the second series of blind vias has a depth that deviates from a mean depth by less than +/−10%.

This application claims priority under 35 USC § 119(e) from U.S. Provisional Patent Application Ser. No. 63/075,871 filed on Sep. 9, 2020 which is incorporated by reference herein in its entirety.

### TECHNICAL FIELD

The present disclosure relates to substrates having a glass composition and that include blind vias having a high degree of uniformity in depth, as well as methods to form such substrates utilizing laser energy to form damaged portions that are subsequently etched.

### BACKGROUND

Glass substrates have been used as an interposer that is disposed between electrical components (e.g., printed circuit boards, integrated circuits, and the like). Glass is a substrate material that is highly advantageous for use as an interposer because glass has dimensional stability, a tunable coefficient of thermal expansion (“CTE”), low electrical loss at high frequencies, electrical performance, high thermal stability, and an ability to be formed at a desired thickness and at large panel sizes. Metalized through vias provide a path through the interposer for electrical signals to pass between opposite sides of the interposer.

The metalized through vias can be formed by first forming blind vias into the substrate. Blind vias do not extend entirely through the interposer but are open at one of the primary surfaces of the substrate. The blind vias are then filled with metal (metalized). The substrate with metalized blind vias is then polished to a final thickness that exposes metal at both primary surfaces of the substrate and thus transforms the metalized blind via into a metalized through via suitable for electrical connection through the substrate.

However, there is a problem in that forming the blind vias into the substrate at a high-speed suitable for commercialization has heretofore resulted in blind vias that have intolerable variability of depth. That is, the depth of the blind vias have too much variation—with some blind vias being too deep or too shallow compared to the specified depth. Excessive variation in depth complicates subsequent processing of the substrate, because variability in the depth of the blind via results in variability amount of metal needed to fill the blind via, in the polishing removal amount needed to expose the via, and in the final shape of the through via. These factors can negatively impact the manufacturing cost and performance as an interposer.

### SUMMARY

The present disclosure addresses that problem by utilizing a line focus of a laser beam to create damaged portions into the substrate contiguous with one or both of the primary surfaces of the substrate. It has been discovered that glass substrates do not have a uniform resistance to damage from the intensity of the line focus of the laser beam. Rather, the resistance to the intensity tends to be strongest in the center of the thickness of the glass substrate and weaker at the primary surfaces. Thus, the depth of the damage that the line focus of the laser beam produces, and whether damage is made contiguous with just one primary surface of the substrate or both primary surfaces, becomes functions of (i) the intensity of the line focus, (ii) the position of the beginning of the line focus relative to one of the primary surfaces of the substrate, and (iii) whether the line focus encompasses the entirety of the thickness of the substrate.

The damage is then etched, leaving blind vias that extend a depth into the thickness of the substrate. The laser is able to generate repeatedly the line focus having generally the same intensity, and etching etches each damaged portion into the substrate at generally the same rate. Thus, the resulting blind vias open to any particular primary surface of the substrate have a generally uniform depth, well within specified tolerances. The blind vias of generally uniform depth can then be metalized with a consistent amount of metal filing each blind via. A subsequent polishing step then thus produces through vias of generally the same shape through the substrate, avoiding the issues that arose with blind vias having excessive variability of depth.

According to a first aspect of the present disclosure, a method of forming blind vias in substrates comprises: (a) transmitting a line focus of a laser beam having a wavelength through a primary surface of a first substrate and into a thickness of the first substrate, the first substrate being transparent to the wavelength of the laser beam, and the line focus having an intensity as a function of depth into the thickness of the first substrate, and the intensity is (i) sufficient to damage the substrate throughout a damaged portion into the thickness of the first substrate contiguous with the primary surface of the first substrate, and (ii) insufficient to damage the first substrate throughout a non-damaged portion that is disposed between the damaged portion and another primary surface of the first substrate.

According to a second aspect of the present disclosure, the method of the first aspect further comprises: (b) repeating (a) while the first substrate is translated relative to an optical axis of the laser beam to form a series of damaged portions into the thickness of the first substrate contiguous with the primary surface.

According to a third aspect of the present disclosure, the method of the second aspect further comprising: contacting the series of damaged portions of the first substrate and the second substrate with an etchant, thus forming a series of blind vias into the thickness of the first substrate that is open to the primary surface; wherein, each blind via of the series of the blind vias into the first substrate has a depth, the series of blind vias into the first substrate has a mean depth, and the depths of the series of blind vias into the first substrate deviate from the mean depth by less than +/−10%.

According to a fourth aspect of the present disclosure, the method of the second aspect further comprising: (c) repeating steps (a) and (b) with a second substrate and either (i) the intensity of the line focus being altered compared to the first substrate, or (ii) a distance between the other primary surface of the second substrate and a beginning of the line focus along the optical axis of the line focus being altered compared to the first substrate; and contacting the series of damaged portions of the first substrate and the second substrate with an etchant, thus forming a series of blind vias into the thickness of the first substrate and the second substrate that are open to the primary surface; wherein, each blind via of the series of the blind vias into the first substrate has a depth, the series of blind vias into the first substrate has a mean depth, and the depths of the series of blind vias into the first substrate deviate from the mean depth by less than +/−10%; wherein, each blind via of the series of the blind vias into the second substrate has a depth, the series of blind vias into the second substrate has a mean depth, and the depths of the series of blind vias into the second substrate deviate from the mean depth by less than +/−10%; and wherein, the mean depth of the series of blind vias formed into the first substrate is different than the mean depth of the series of blind vias formed into the second substrate.

According to a fifth aspect of the present disclosure, the fourth aspect, wherein step (c) comprises repeating steps (a) and (b) with the second substrate and the intensity of the line focus being altered compared to the first substrate.

According to a sixth aspect of the present disclosure, the fourth aspect, wherein step (c) comprises repeating steps (a) and (b) with the second substrate and the distance between the other primary surface of the second substrate and the beginning of the line focus along the optical axis of the line focus being altered compared to the first substrate.

According to a seventh aspect of the present disclosure, any one of the first through sixth aspects, wherein the intensity of the line focus is substantially uniform along the optical axis.

According to an eighth aspect of the present disclosure, any one of the first through sixth aspects, wherein the intensity of the line focus is not substantially uniform along the optical axis and varies as a function of position within the thickness of the substrate.

According to a ninth aspect of the present disclosure, anyone of the fourth through sixth aspects, wherein the first substrate and the second substrate both comprise glass; a picosecond laser produces the laser beam in a burst of pulses; and one burst of less than 5 pulses generates the damaged portion.

According to a tenth aspect of the present disclosure, the method of any one of the third through sixth or ninth aspects further comprising: depositing metal within the series of blind vias of the first substrate.

According to an eleventh aspect of the present disclosure, a method of forming blind vias comprises: (a) transmitting a line focus of a laser beam having a wavelength into the entirety of a thickness of a substrate that is transparent to the wavelength of the laser beam, the line focus having an intensity as a function of depth into the thickness of the substrate, and the intensity is (i) sufficient to damage the substrate throughout a first damaged portion into the thickness of the substrate contiguous with a first primary surface of the substrate, (ii) sufficient to damage the substrate throughout a second damaged portion into the thickness of the substrate contiguous with a second primary surface of the substrate, and (iii) insufficient to damage the substrate throughout a non-damaged portion that is disposed between the first damaged portion and the second damaged portion.

According to a twelfth aspect of the present disclosure, the method of the eleventh aspect further comprises: (b) repeating (a) while the substrate is translated relative to the laser beam to form a series of first damaged portions into the thickness of the substrate contiguous with the first primary surface, and a series of second damaged portions into the thickness of the substrate contiguous with the second primary surface.

According to a thirteenth aspect of the present disclosure, the method of the twelfth aspect further comprises: (c) contacting the series of first damaged portions and the series of second damaged portions of the substrate with an etchant, thus forming (i) a first series of blind vias into the thickness of the substrate and open to the first primary surface and (ii) a second series of blind vias into the thickness of the substrate and open to the second primary surface.

According to a fourteenth aspect of the present disclosure, the thirteenth aspect, wherein each of the blind vias of the first series of blind vias is coaxial with one blind via of the second series of blind vias.

According to a fifteenth aspect of the present disclosure, the method of any one of the thirteenth through fourteenth aspects further comprising: depositing metal within the first series of blind vias and the second series of blind vias.

According to a sixteenth aspect of the present disclosure, any one of the eleventh through fifteenth aspects, wherein the substrate comprises glass; a picosecond laser produces the laser beam in a burst of pulses; and one burst of less than 5 pulses generates one first damaged portion of the series of first damaged portions and one second damaged portion of the series of second damaged portions.

According to a seventeenth aspect of the present disclosure, any one of the eleventh through sixteenth aspects, wherein the intensity of the line focus is substantially uniform.

According to an eighteenth aspect of the present disclosure, any one of the eleventh through sixteenth aspects, wherein the intensity of the line focus is substantially uniform throughout a first intensity region that forms the first damaged portion; the intensity of the line focus is substantially uniform throughout a second intensity region that forms the second damaged portion; and the intensity of the line focus is substantially uniform throughout a second intensity region that forms the second damaged portion; and

According to a nineteenth aspect of the present disclosure, any one of the eleventh through sixteenth aspects, wherein the intensity of the line focus is not substantially uniform and varies as a function of position within the thickness of the substrate.

According to a twentieth aspect of the present disclosure, any one of the thirteenth through fifteenth aspects, wherein each blind via of the first series of blind vias and the second series of blind vias has an interior wall, and the interior wall includes a first tapered region and a second tapered region, wherein the first tapered region and the second tapered region have a different slope.

According to a twenty-first aspect of the present disclosure, any one of the thirteenth through fifteenth and twentieth aspects, wherein each blind via of the first series of blind vias has a depth, the first series of blind vias has a mean depth, and the depths of the first series of blind vias deviate from the mean depth by less than +/−10%; and each blind via of the second series of blind vias has a depth, the second series of blind vias has a mean depth, and the depths of the second series of blind vias deviate from the mean depth by less than +/−10%.

According to a twenty-second aspect of the present disclosure, any one of the thirteenth through fifteenth, twentieth, and twenty-first aspects, wherein the etchant is an aqueous solution comprising hydrofluoric acid.

According to a twenty-third aspect of the present disclosure, the method of any one of the eleventh and sixteenth through nineteenth aspects further comprising: (c) repeating steps (a) and (b) with a second substrate and the intensity of the line focus being altered compared to the substrate; and (d) contacting the series of first damaged portions and the series of second damaged portions of the substrate and the second substrate with an etchant, thus forming (i) a first series of blind vias into the thickness of the substrate and the second substrate that are open to the first primary surface and (ii) a second series of blind vias into the thickness of the substrate and the second substrate that are open to the second primary surface; wherein, each blind via of the first series of the blind vias into the substrate has a depth, the first series of blind vias into the substrate has a mean depth, and the depths of the first series of blind vias into the substrate deviate from the mean depth by less than +/−10%; wherein, each blind via of the second series of the blind vias into the substrate has a depth, the second series of blind vias into the substrate has a mean depth, and the depths of the second series of blind vias into the substrate deviate from the mean depth by less than +/−10%; wherein, each blind via of the first series of the blind vias into the second substrate has a depth, the first series of blind vias into the second substrate has a mean depth, and the depths of the first series of blind vias into the second substrate deviate from the mean depth by less than +/−10%; wherein, each blind via of the second series of the blind vias into the second substrate has a depth, the second series of blind vias into the second substrate has a mean depth, and the depths of the second series of blind vias into the second substrate deviate from the mean depth by less than +/−10%; wherein, the mean depth of the first series of blind vias formed into the substrate are different than the mean depth of the first series of blind vias formed into the second substrate; and wherein, the mean depth of the second series of blind vias formed into the substrate are different than the mean depth of the second series of blind vias formed into the second substrate.

According to a twenty-fourth aspect of the present disclosure, the method of any one of the eleventh and sixteenth through nineteenth aspects further comprising: (c) repeating steps (a) and (b) with a second substrate and the distance between a first primary surface of the second substrate and a beginning of the line focus along an optical axis of the line focus being altered compared to the substrate; and (d) contacting the series of first damaged portions and the series of second damaged portions of the substrate and the second substrate with an etchant, thus forming (i) a first series of blind vias into the thickness of the substrate and the second substrate that are open to the first primary surface and (ii) a second series of blind vias into the thickness of the substrate and the second substrate that are open to the second primary surface; wherein, each blind via of the first series of the blind vias into the substrate has a depth, the first series of blind vias into the substrate has a mean depth, and the depths of the first series of blind vias into the substrate deviate from the mean depth by less than +/−10%; wherein, each blind via of the second series of the blind vias into the substrate has a depth, the second series of blind vias into the substrate has a mean depth, and the depths of the second series of blind vias into the substrate deviate from the mean depth by less than +/−10%; wherein, each blind via of the first series of the blind vias into the second substrate has a depth, the first series of blind vias into the second substrate has a mean depth, and the depths of the first series of blind vias into the second substrate deviate from the mean depth by less than +/−10%; wherein, each blind via of the second series of the blind vias into the second substrate has a depth, the second series of blind vias into the second substrate has a mean depth, and the depths of the second series of blind vias into the second substrate deviate from the mean depth by less than +/−10%; wherein, the mean depth of the first series of blind vias formed into the substrate are different than the mean depth of the first series of blind vias formed into the second substrate; and wherein, the mean depth of the second series of blind vias formed into the substrate are different than the mean depth of the second series of blind vias formed into the second substrate.

According to a twenty-fifth aspect of the present disclosure, the method of the twelfth aspect further comprising: dividing the substrate into an alpha substrate and a beta substrate, with the alpha substrate including the series of first damaged portions and the beta substrate including the second damaged portions; and contacting the series of first damaged portions and the series of second damaged portions with an etchant, thus forming (i) a series of blind vias into the alpha substrate and (ii) a series of blind vias into the beta substrate.

According to a twenty-sixth aspect of the present disclosure, the method of any one of the thirteenth through fifteenth and twentieth through twenty-second further comprising: dividing the substrate into an alpha substrate and a beta substrate, with the alpha substrate including the first series of blind vias and the beta substrate including the second series of blind vias.

According to a twenty-seventh aspect of the present disclosure, a substrate comprises: a first series of blind vias into a thickness of a substrate and open to a first primary surface, each blind via of the first series of blind vias having an interior wall, the interior wall having a first tapered region and a second tapered region, wherein the first tapered region and the second tapered region have a distinct slope; and a second series of blind vias into the thickness of a substrate and open to a second primary surface, each of the blind vias of the second series of blind vias being coaxial with a different blind via of the first series of blind vias, and each blind via of the second series of blind vias having an interior wall, the interior wall having a first tapered region and a second tapered region, wherein the first tapered region and the second tapered region of the second series of blind vias have a different slope.

According to a twenty-eighth aspect of the present disclosure, the twenty-seventh aspect, wherein each blind via of the first series of blind vias has a depth, the first series of blind vias has a mean depth, and the depths of the first series of blind vias deviate from the mean depth by less than +/−10%; and each blind via of the second series of blind vias has a depth, the second series of blind vias has a mean depth, and the depths of the second series of blind vias differ by less than +/−10% from the mean depth.

According to a twenty-ninth aspect, the substrate of any one of the twenty-seventh through twenty-eighth aspects further comprising: metal disposed within each blind via of the first series of blind vias and the second series of blind vias.

According to a thirtieth aspect, any one of the twenty-seventh through twenty-ninth aspects, wherein the substrate is divisible at a division within the thickness into an alpha substrate and a beta substrate, with the alpha substrate including the first series of blind vias and the beta substrate including the second series of blind vias.

According to a thirty-first aspect, the method of any one of the twenty-seventh through thirtieth aspects further comprises: a non-damaged portion disposed between each blind via of the first series of blind vias and each blind via of the second series of blind vias, wherein, each blind via of the first series of blind vias is coaxial about an axis with one blind via of the second series of blind vias, and the axis extends through the non-damaged portion.

### BRIEF DESCRIPTION OF THE DRAWINGS

In the Figures:

FIG. 1A is a perspective view of a substrate that can be formed following embodiments of a method disclosed herein, illustrating a first series of blind vias open to a first primary surface of the substrate, and a second primary surface facing a generally opposite direction of the first primary surface;

FIG. 1B is a perspective view of the substrate of FIG. 1A, illustrating a series of blind vias open to the second surface of the substrate;

FIG. 2 is an elevation view of the cross-section of the substrate of FIG. 1A taken through the line II-II of FIGS. 1A and 1B, illustrating the substrate having a thickness from the first primary surface to the second primary surface, and the blind vias of both the first series and the second series not extending entirely through the thickness, and additionally illustrating that the substrate may be divided through the thickness into an alpha substrate with the first series of blind vias and a beta substrate with the second series of blind vias;

FIG. 3 is an elevation view of area III of FIG. 2, illustrating a pair of blind vias (one blind via from each of the first series and the second series of blind vias) that are coaxial about an axis, and have an interior wall with a first tapered region, a second tapered region, and a third tapered region, which all have a distinct slope, as well as a depth from the first primary surface or the second primary surface to which the blind via is open;

FIG. 4 is the same view as FIG. 3 but further illustrating metal filling the blind vias, after a metallization step of embodiments of the method;

FIG. 5 is a block diagram of embodiments of the method to form a substrate of FIG. 1A, illustrating steps of (i) transmitting a line focus of a laser beam into the thickness of the substrate with sufficient intensity to create a first damaged portion and a second damaged portion into the thickness of the substrate but insufficient to damage the substrate throughout a non-damaged portion disposed between the first damaged portion and the second damaged portion, (ii) translating the substrate relative to the line focus and repeating step (i) to create a series of the first damaged portions and a series of the second damaged portions, and (iii) etching the series of the first damaged portions and the second damaged portions to generate the first series of blind vias and the second series of blind vias;

FIG. 6A is a cross-sectional view of the substrate during the method of FIG. 5 according to embodiments where the intensity of the laser beam is non-uniform and varies as a function of position through the thickness of the substrate;

FIG. 6B is a conceptual schematic of an axicon and reimaging optical system used to generate the line focus of FIG. 6A with the non-uniform intensity;

FIG. 6C is a cross-sectional view of the laser beam subsequently forming the line focus of FIG. 6A with the non-uniform intensity, illustrating rings centered about a center portion along the optical axis;

FIG. 6D is a graph of peak intensity of the laser beam of FIG. 6A as a function of distance along the optical axis after leaving the reimaging optical system, illustrating the line focus beginning and ending where the peak intensity is 50 percent of the maximum peak intensity within the line focus;

FIG. 7A is a cross-sectional view of the substrate during the method of FIG. 5 according to embodiments where the intensity of the laser beam is substantially uniform as a function of position through the thickness of the substrate;

FIG. 7B is a graph of peak intensity of the laser beam of FIG. 7A as a function of distance along the optical axis, illustrating that the peak intensity of the line focus is constant for a high percentage of the length of the line focus;

FIG. 7C is a conceptual schematic of an optical system used to transform the laser beam having a Gaussian profile into the line focus formed by rays intersecting the optical axis at substantially the same angle and forming segments of the length of the line focus having substantially the same intensity;

FIG. 7D is a conceptual schematic of an axicon of the optical system of FIG. 7C, illustrating the axicon having an aspheric exit surface that forms regions of the length of the line focus having substantially the same length and substantially the same intensity but the rays not having the same angle of intersection with the optical axis;

FIG. 7E is a conceptual schematic of the optical system of FIG. 7C, illustrating a first optical component and second optical component having a couplet of two lenses, all of which modify the laser beam leaving the axicon to have the line focus of FIG. 7A with rays of the laser beam intersecting the optical axis at substantially the same angle and equal segments of the length of the line focus having substantially the same intensity;

FIG. 8A is a cross-sectional view of the substrate during the method of FIG. 5 according to embodiments where the intensity of the laser beam is substantially uniform throughout a first intensity region encompassing the first primary surface and a second intensity region comprising the second primary surface, and the intensities of the first intensity region and the second intensity region are different, thus creating the series of first damaged portions extending into the thickness to a different extent than the series of second damaged portions;

FIG. 8B is a conceptual schematic diagram of a spatial light modulator and a reimaging optical system generating the line focus of FIG. 8A having the first intensity region and the second intensity region from a laser beam having a Gaussian intensity profile produced by the laser;

FIG. 9A is the same cross-sectional view as FIG. 6A but illustrating the intensity of the line focus being altered from an initial intensity for the substrate to a lower intensity or a higher intensity for a second substrate, pursuant to an optional step of the method of FIG. 5, which changes the extent to which the first damaged portions and the second damaged portions extend into the thickness of the second substrate compared to the substrate;

FIG. 9B is the same cross-sectional view as FIG. 7A but illustrating the intensity of the line focus being altered from an initial intensity for the substrate to a lower intensity or a higher intensity for the second substrate, pursuant to an optional step of the method of FIG. 5, which changes the extent to which the first damaged portions and the second damaged portions extend into the thickness of the second substrate compared to the substrate;

FIG. 9C is the same cross-sectional view as FIG. 8A but illustrating the intensity of the line focus being altered from an initial intensity for the substrate to a lower intensity or a higher intensity for the second substrate, pursuant to an optional step of the method of FIG. 5, which changes the extent to which the first damaged portions and the second damaged portions extend into the thickness of the second substrate compared to the substrate;

FIG. 9D is the same cross-sectional view as FIG. 6A but illustrating a distance between the first primary surface of the substrate and the beginning of the line focus being altered from an initial distance for the substrate to a shorter distance or a longer distance for the second substrate, pursuant to an optional step of the method of FIG. 5, which changes the extent to which the first damaged portion and the second damaged portion extend into the thickness of the second substrate compared to the substrate;

FIG. 10A is a schematic diagram of a step of the method of FIG. 5, illustrating the substrate with the series of first damaged portions and the series of second damaged portions being contacted with an etchant, which forms the first series of blind vias and the second series of blind vias from the series of first damaged portions and the series of second damaged portions;

FIG. 10B is a cross-sectional view of the substrate and the second substrate after altering the intensity of the line focus as in FIGS. 9A-9C or altering the distance as in FIG. 9D, and after the etching step of the method of FIG. 10A, illustrating the resulting blind vias having different depths;

FIG. 11 is a block diagram of embodiments of a method of forming blind vias into substrates, illustrating steps of (i) transmitting the line focus of the laser beam into the substrate encompassing one of the primary surfaces of the substrate to create damaged portions, (ii) translating laterally the substrate, and (iii) repeating (i) and (i) with the second substrate and either altering the intensity of the line focus or the distance between the first primary surface and the beginning of the line focus compared to the substrate;

FIG. 12A is a cross-sectional view of the substrate and the second substrate during the method of FIG. 11, illustrating increased (uniform) intensity of the line focus for the second substrate generating a series of damaged portions that extends deeper into the thickness of the second substrate than the series damaged portions into the substrate generated with the initial intensity;

FIG. 12B is a cross-sectional view of the substrate and the second substrate during the method of FIG. 11, illustrating increased distance between the first primary surface of the second substrate and the beginning of the line focus, which has uniform intensity, generating a series of damaged portions that extends less into the thickness of the second substrate than the series of damaged portions into the substrate generated with the initial distance;

FIG. 13A is a cross-sectional view of the substrate and the second substrate during the method of FIG. 11, illustrating increased (not uniform) intensity of the line focus for the second substrate generating a series of damaged portions that extends deeper into the thickness of the second substrate than the series of damaged portions into the substrate generated with the initial intensity;

FIG. 13B is a cross-sectional view of the substrate during the method of FIG. 11, illustrating increased distance between the first primary surface of the second substrate and the beginning of the line focus, which has non-uniform intensity, generating a series of damaged portions that extends deeper into the thickness of the second substrate than the series of damaged portions generated into the substrate with the initial distance;

FIG. 14 is a cross-sectional view of the substrate and the second substrate each with the series of blind vias open to the second primary surface formed with the method of FIG. 11, illustrating blind vias into the substrate having a different depth than the depth of blind vias into the second substrate;

FIG. 15, pertaining to Example 1, depicts blind vias formed into three samples of a substrate, the intensity of the line focus used to form damaged portions from which the blind vias were generated being different for each sample, and the distance between the beginning of the line focus and the first primary surface to form damaged portions from which the blind vias were generated being different for Sample 3;

FIG. 16, pertaining to Example 2, depicts blind vias formed into a sample of the substrate, all formed from damaged portions generated with the same intensity and distance, and a graph showing that the blind vias have a relatively uniform depth;

FIG. 17, pertaining to Example 3, depicts a first series of blind vias (open to the first primary surface) and a second series of blind vias (open to the second primary surface) formed into two samples of the substrate, the intensity of the line focus being the same for both samples but the distance between the first primary surface and the beginning of the line focus being different;

FIG. 18, pertaining to Example 4, depicts a first series of blind vias (open to the first primary surface) and a second series of blind vias (open to the second primary surface) formed into three samples of the substrate, the intensity of the line focus being sequentially increased for each sample; and

FIG. 19, pertaining to Example 5, depicts a first series of blind vias (open to the first primary surface) and a second series of blind vias (open to the second primary surface) formed into a sample of the substrate, and a graph showing the relatively uniform depths for the first series of blind vias and the second series of blind vias.

### DETAILED DESCRIPTION

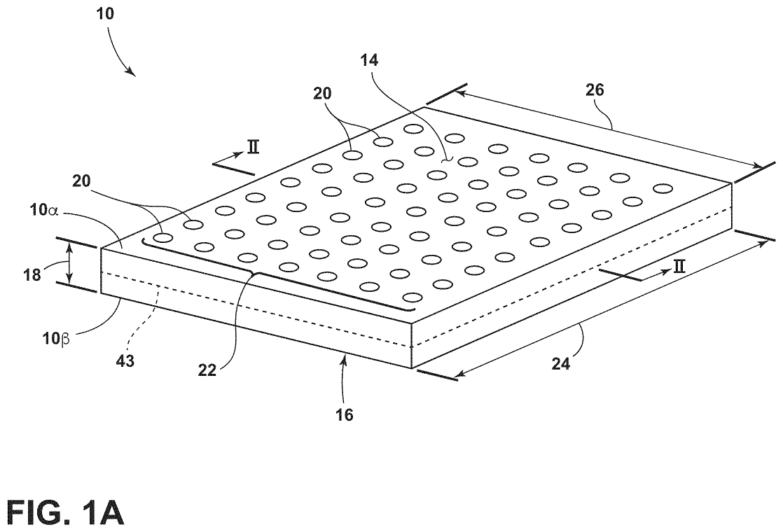

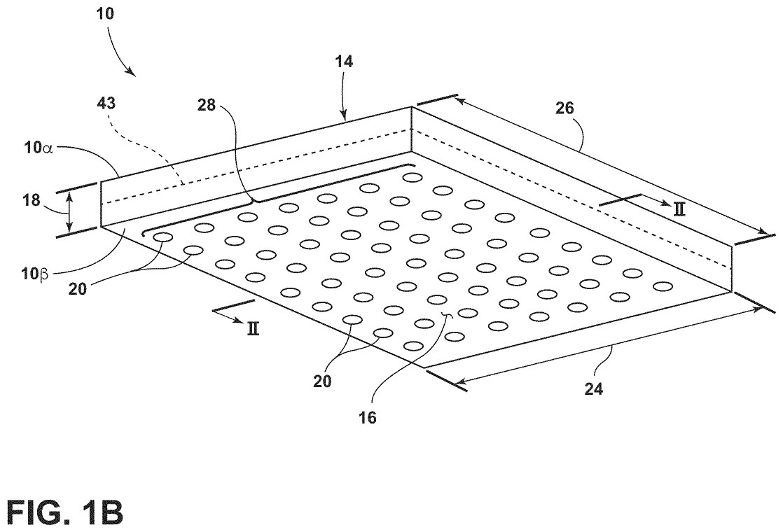

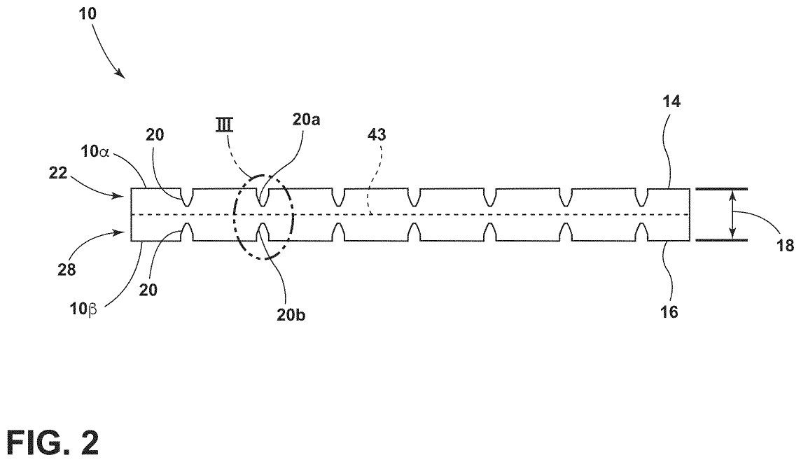

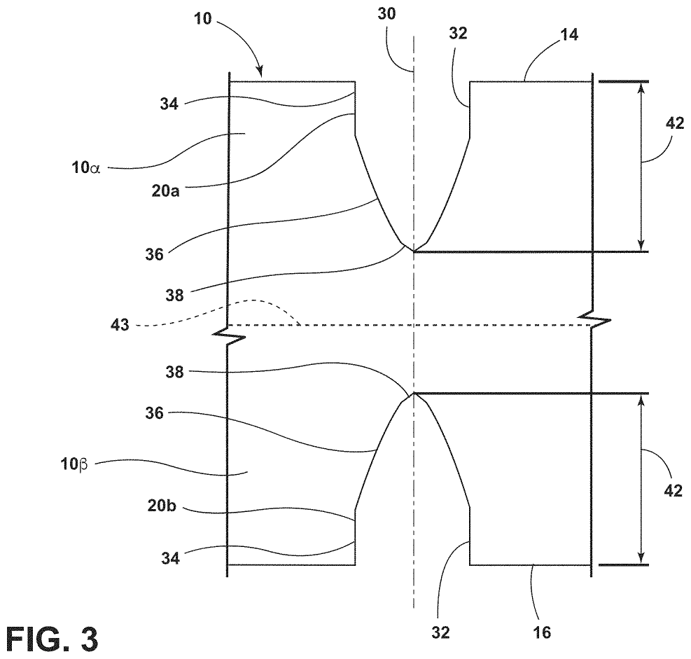

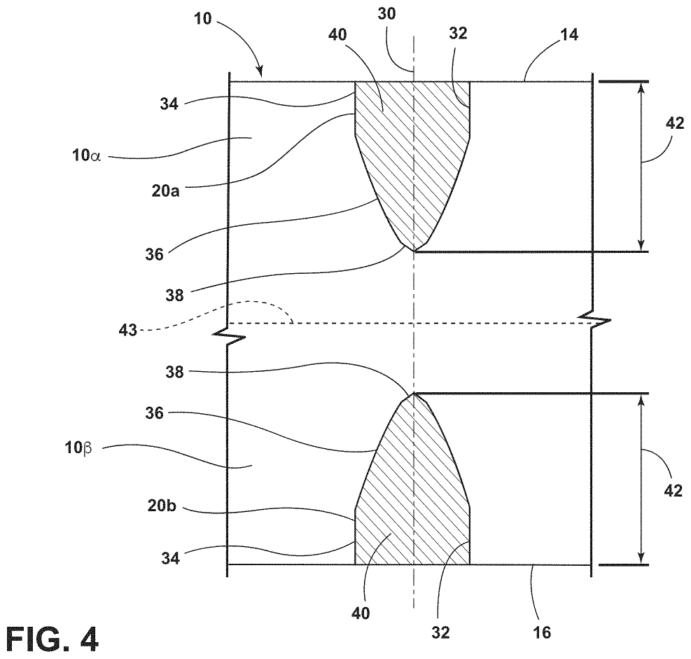

Referring now to FIGS. 1A-4, a substrate 10, which may be formed according to embodiments of a method 12, is described herein. The substrate 10 has a first primary surface 14, a second primary surface 16, and a thickness 18 between the first primary surface 14 and the second primary surface 16. The substrate 10 includes at least one blind via 20 that extends into the thickness 18 of the substrate 10 and that is open to the first primary surface 14. In embodiments, the at least one blind via 20 is one of a first series 22 of blind vias 20, all of which extend into the thickness 18 of the substrate 10 and are open to the first primary surface 14. In embodiments, the thickness 18 of the substrate 10 is 50 μm to 1 mm. In embodiments, the substrate 10 is a sheet with a length 24 and a width 26 that are orthogonal to the thickness 18.

In embodiments, the substrate 10 includes at least one blind via 20 that is open to the second primary surface 16 and that extends into thickness 18 of the substrate 10. The at least one blind via 20 can be one of a second series 28 of blind vias 20, all of which extend into the thickness 18 of the substrate 10 and are open to the second primary surface 16. In embodiments, each of the bind vias 20 of the second series 28 of blind vias 20 are coaxial with one blind via 20 of the first series 22 of blind vias 20. For example, both the blind via 20a open to the first primary surface 14 and the blind via 20b open to the second primary surface 16 are centered about an axis 30. In embodiments, the first primary surface 14 and the second primary surface 16 are substantially planar and parallel to each other. In embodiments, the axes 30 extending through pairs of the first series 22 and the second series 28 of blind vias 20 are orthogonal to both the first primary surface 14 and the second primary surface 16.

Each blind via 20 has an interior wall 32. In embodiments, the interior wall 32 has a first tapered region 34 and a second tapered region 36. The interior wall 32 can have additional tapered regions such as a third tapered region 38. In embodiments, the first tapered region 34, the second tapered region 36, and any additional tapered regions have a distinct slope.

Each blind via 20 has a depth 42. Collectively, in embodiments, the first series 22 of blind vias 20 has a mean depth 42. By following the method 12 described herein, the depths 42 of the first series 22 of blind vias 20 deviate from the mean depth 42 of the entire first series 22 by less than +/−10%. For example, if the mean depth 42 of the first series 22 of blind vias 20 is 100 μm, then to deviate from the mean depth 42 by +/−10% or less, the depths 42 of the first series 22 of blind vias 20 are within the range of 90 μm to 110 μm. In embodiments, the depths 42 of the first series 22 of blind vias 20 deviate from the mean depth by +/−9% or less, +/−8% or less, +/−7% or less, +/−6% or less, +/−5% or less, +/−4% or less, +/−3% or less, +/−2% or less, +/−1% or less, or +/−<1%.

Likewise, in embodiments, the second series 28 of blind vias 20 collectively has a mean depth 42. By following the method 12 further described herein, the depths 42 of the second series 28 of blind vias 20 deviate from the mean depth 42 by +/−10% or less. In embodiments, the depths 42 of the second series 28 of blind vias 20 deviate from the mean depth 42 by +/−9% or less, +/−8% or less, +/−7% or less, +/−6% or less, +/−5% or less, +/−4% or less, +/−3% or less, +/−2% or less, +/−1% or less, or +/−<1%. The mean depth 42 of the second series 28 of blind vias 20 can be shallower or deeper than the mean depth 42 of the first series 22 of blind vias 20. In embodiments, the mean depth 42 of the second series 28 of blind vias 20 is 75 percent or less, such as 25 percent to 75 percent of the mean depth 42 of the first series 22 of blind vias 20. In other embodiments, the mean depth 42 of the second series 28 of blind vias 20 is 125 percent or more, such as 125 percent to 250 percent of the mean depth 42 of the first series 22 of blind vias 20.

In embodiments, the substrate 10 further comprises metal 40 disposed within each blind via 20 of the first series 22 and the second series 28 of blind vias 20.

In embodiments, the substrate 10 is divisible at a division 43 into an alpha substrate 10α and a beta substrate 10β. The words “alpha” and “beta” are used only to differentiate the alpha substrate 10α from the beta substrate 10β. For the method 12 described herein, the alpha substrate 10α and the beta substrate 10β, as distinct pieces, may be stacked together to form the substrate 10 subjected to the method 12 and thereafter re-divided at the division 43. Alternatively, the substrate 10 can be subjected to the method 12 as a solitary piece and later separated at the division 43 into the alpha substrate 10α and the beta substrate 10β. The alpha substrate 10α includes the first series 22 of blind vias 20. The beta substrate 10β includes the second series 28 of blind vias 20. Each of the alpha substrate 10α and the beta substrate 10β may make up approximately half of the thickness 18 of the substrate 10, although the alpha substrate 10α can make up a greater or less proportion of the thickness 18 of the substrate 10 than the beta substrate 10β. This divisibility allows for two substrates 10α and 10β to be manipulated or formed simultaneously, which decreases expense and required time.

In embodiments, the substrate 10 comprises glass. The glass can have various compositions including, without limitation, borosilicate, aluminosilicate, aluminoborosilicate, and soda lime compositions. Further, the glass may be strengthened (e.g., by an ion exchange process) or non-strengthened. The discussion herein about the composition of the substrate 10 applies equally as well to the alpha substrate 10α and the beta substrate 10β. In embodiments, the composition of the alpha substrate 10α is the same as the composition of the beta substrate 10β. In other embodiments, the composition of the alpha substrate 10α is different than the composition of the beta substrate 10β.

The substrate 10 can have any one of a wide range of compositions resulting in the ability to closely match the coefficient of thermal expansion (CTE) of the substrate 10 with the materials that are intended to be adjacent to the substrate 10 in the application of the substrate 10, such as the application as an interposer that will be adjacent to silicon components. For instance, the substrate 10 can have a composition such that it has a CTE of 3.0 ppm/° C. to 3.5 ppm/° C., which resembles the CTE of silicon. However, in other embodiments, the substrate 10 can have any desired CTE of 3.0 ppm/° C. to 12.0 ppm/° C.

For example, in embodiments, the substrate 10 comprises (in mole percent on an oxide basis, inclusive of end points): SiO₂: 64.0 to 71.0; Al₂O₃: 9.0 to 12.0; B₂O₃: 7.0 to 12.0; MgO: 1.0 to 3.0; CaO: 6.0 to 11.5; SrO: 0 to 2.0; BaO: 0 to 0.1, wherein: (a) 1.00≤Σ[RO]/[Al₂O₃≤]1.25, where [Al₂O₃] is the mole percent of Al₂O₃ and Σ[RO] equals the sum of the mole percents of MgO, CaO, SrO, and BaO; and (b) the composition has at least one of the following characteristics: (i) on an oxide basis, the composition comprises at most 0.05 mole percent Sb₂O₃; and (ii) on an oxide basis, the glass comprises at least 0.01 mole percent SnO₂. Such a composition results in the substrate 10 having a CTE in a range of about 3.0 ppm/° C. to 3.5 ppm/° C.

As another example, in embodiments, the substrate 10 comprises (in mole percent on an oxide basis): 69.2 mol % SiO₂, 8.5 mol % Al₂O₃, 13.9 mol % Na₂O, 1.2 mol % K₂O, 6.5 mol % MgO, 0.5 mol % CaO, and 0.2 mol % SnO₂. Such a composition results in the substrate 10 having a CTE of about 6.0 ppm/° C.

As another example, the substrate 10 comprises (in mole percent on an oxide basis, inclusive of end points): SiO₂: 64.0 to 72.0; Al₂O₃: 9.0 to 16.0; B₂O₃: 1.0 to 5.0; MgO+La₂O₃: 1.0 to 7.5; CaO: 2.0 to 7.5; SrO: 0.0 to 4.5; BaO: 1.0 to 7.0, wherein Σ(MgO+CaO+SrO+BaO+3La₂O₃)/(Al₂O₃)≥1.15, where Al₂O₃, MgO, CaO, SrO, BaO, and La₂O₃ represent the mole percents of the respective oxide components. This composition is alkali-free and results in the substrate 10 having a CTE of about 10.0 ppm/° C.

In other embodiments, the substrate 10 is high purity fused silica. High purity fused silica has a composition (on an oxide basis) of at least 99.9 mol % SiO₂ and the SiO₂ is generally amorphous, having less than 1 wt % crystalline content.

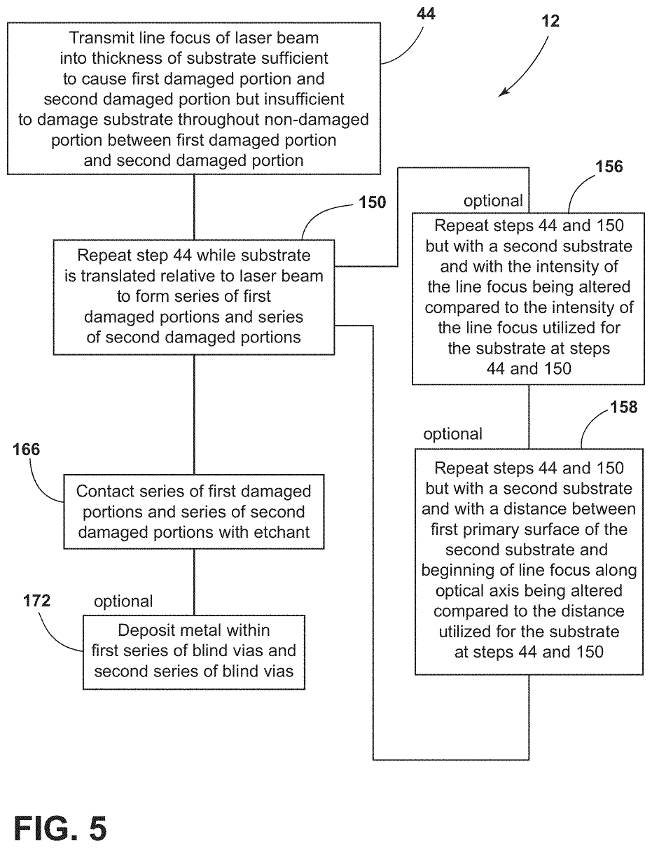

Referring now to FIGS. 5-11, the method 12 of forming the blind vias 20 is herein described. In step 44, the method 12 comprises transmitting a line focus 46 of a laser beam 48 into an entirety of the thickness 18 of the substrate 10. The laser beam 48 has a wavelength 50. The wavelength 50 of the laser beam 48 may be, for example, 1064 nm or less, such as 1064 nm, 1030 nm, 532 nm, 530 nm, 355 nm, 343 nm, or 266 nm, or a wavelength of 266 nm to 1064 nm. The substrate 10 is transparent to the wavelength 50 of the laser beam 48. A substrate 10 is transparent to the wavelength 50 when the absorption is less than 10% per mm of substrate 10 depth at the wavelength 50. In embodiments, the absorption is less than 1% per mm of substrate 10 depth at the wavelength 50.

The line focus 46 is a region whereby the focused spot of the laser beam 48 is maintained over a length 52 that is longer than expected by the typical diffraction properties of a same sized single focus spot formed by a Gaussian laser beam 48. Instead of the beam being focused to a point (or at least a very short region), the laser beam 48 corresponding to the line focus 46 is being focused to an extended region along the beam propagation direction. The length 52 of the line focus 46 is the distance (within the line focus 46, along an optical axis 54 of the direction of propagation) between a beginning 56 and an end 58 where the peak cross sectional beam intensity 60 is half of its maximum peak value 62 (lₘₐₓ). One strategy for forming a line focus 46 is to form a quasi-non-diffracting laser beam 48, which employs a more sophisticated laser beam 48 profile, such as a Bessel or a Gauss-Bessel profile, instead of employing a Gaussian laser beam 48 profile that a laser 64 commonly generates. These more sophisticated Bessel and Gauss-Bessel laser beam 48 profiles diffract much more slowly than a laser beam 48 having a Gaussian profile.

As mentioned in the Summary above, the substrate 10 has a resistance 66 to the intensity 60 of the line focus 46. If the intensity 60 of the line focus 46 is greater than the resistance 66 of the substrate 10 to the intensity 60, then the line focus 46 induces multi-photon absorption (MPA) that damages the substrate 10. MPA is the simultaneous absorption of multiple photons of identical or different frequencies in order to excite a material from a lower energy state (usually the ground state) to a higher energy state (excited state). The excited state may be an excited electronic state or an ionized state. The energy difference between the higher and lower energy states of the material is equal to the sum of the energies of the two or more photons. MPA is a nonlinear process that is several orders of magnitude weaker than linear absorption. In the case of two-photon absorption, it differs from linear absorption in that the strength of absorption depends on the square of the light intensity 60, thus making it a nonlinear optical process. At ordinary light intensities 60, MPA is negligible. If the light intensity 60 (energy density) is extremely high, such as in the line focus 46 of the laser beam 48 (particularly from a pulsed laser 64), MPA becomes appreciable and leads to measurable effects (damage) in the substrate 10 within the region where the intensity 60 of the laser beam 48 exceeds the resistance 66 of the substrate 10 to the intensity 60. These measurable effects include ionization, breaking of molecular bonds, and, in some instances, vaporization of substrate 10. In other words, MPA can result in a local reconfiguration and separation of the excited atoms or bonds from adjacent atoms or bonds. The resulting modification in the bonding or configuration can result in non-thermal ablation and removal of matter from the region of the material in which MPA occurs.

At the atomic level, the ionization of individual atoms has discrete energy requirements. Several elements commonly used in glass compositions for the substrate 10 (e.g., Si, Na, K) have relatively low ionization energies (˜5 eV). Without the phenomenon of MPA, a wavelength 50 of about 248 nm would be required to create linear ionization at ˜5 eV. With MPA, ionization or excitation between states separated in energy by ˜5 eV can be accomplished with wavelengths 50 longer than 248 nm. For example, photons with a wavelength 50 of 532 nm have an energy of ˜2.33 eV, so two photons having a wavelength 50 of 532 nm can induce a transition between states separated in energy by ˜4.66 eV in two-photon absorption (TPA), for example.

For the method 12, the length 52 of the line focus 46 is equal to or longer than the thickness 18 of the substrate 10, and the length 52 of the line focus 46 subsumes the thickness 18 of the substrate 10. In other words, the first primary surface 14 and the second primary surface 16 of the substrate 10 are disposed between the beginning 56 and the end 58 of the line focus 46. In embodiments, the length 52 of the line focus 46 is 0.3 mm to 10 mm and has an average spot diameter (over its length 52) between 0.1 micron and about 5 microns (e.g., 0.2 microns to 1 or 2 microns).

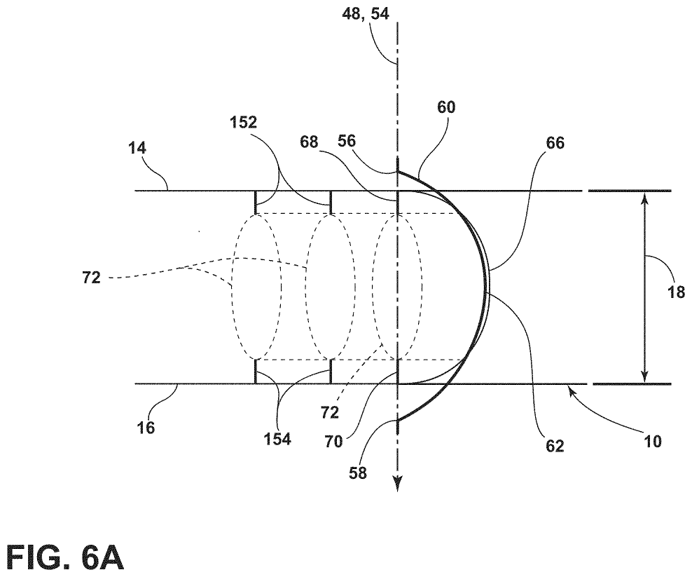

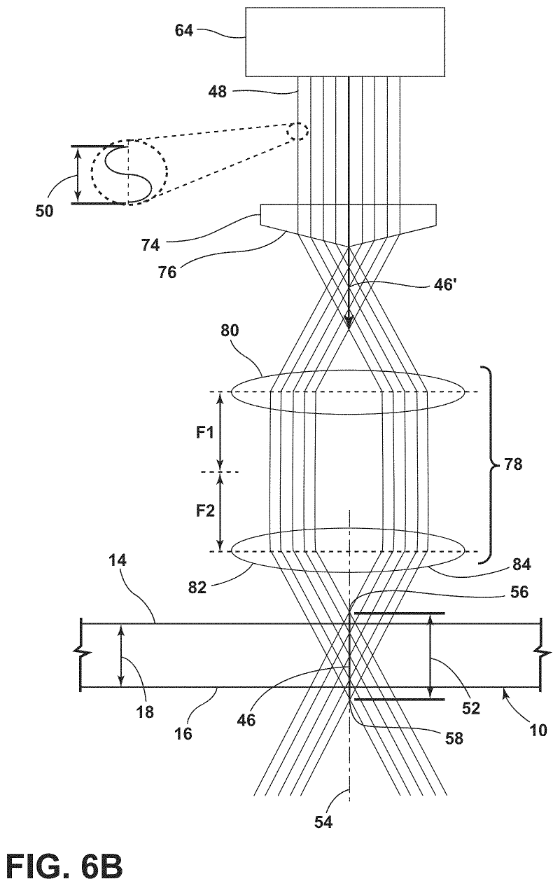

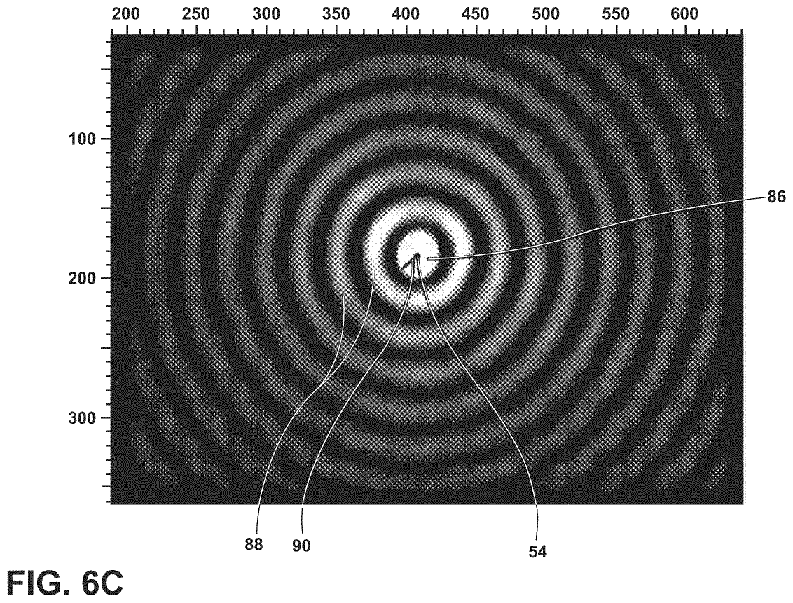

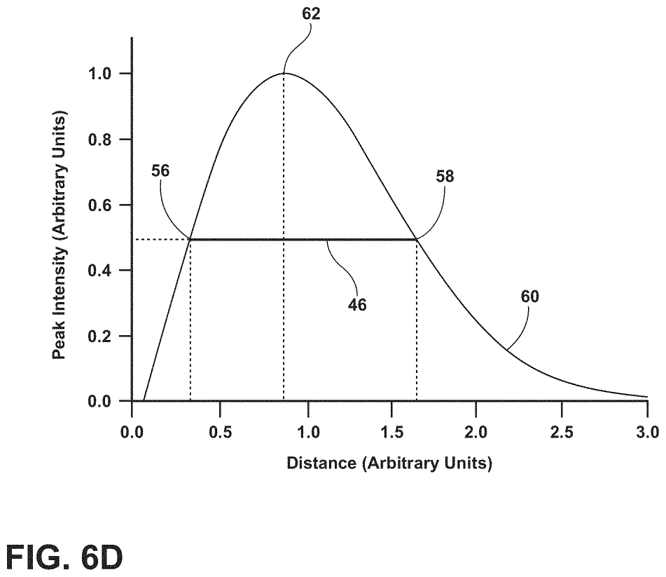

As mentioned, the line focus 46 has an intensity 60 as a function of depth into the thickness 18 of the substrate 10. This aspect is conceptually illustrated at figures, such as FIG. 6A, where the relative intensity 60 of the line focus 46 as a function of position throughout the thickness 18 of the substrate 10 is illustrated, according to embodiments. The further the line representing the intensity 60 of the line focus 46 is to the right from the centralized vertical line representing the laser beam 48, the greater the intensity 60 of the line focus 46.

In addition, as mentioned above, the resistance 66 of the substrate 10 to damage from the laser beam 48 is also a function of depth into the thickness 18 of the substrate 10, with the resistance 66 varying as a function of depth into the thickness 18. This aspect is also conceptually illustrated at figures, such as FIG. 6A, where the relative resistance 66 of the substrate 10 to damage from the laser beam 48 is illustrated, according to embodiments. The further the line representing the resistance 66 of the substrate 10 to damage from the laser beam 48 is to the right from the centralized vertical line representing the laser beam 48, the greater the resistance 66 to the substrate 10 to damage from the laser beam 48. When the intensity 60 of the line focus 46 of the laser beam 48 as a function of depth into the thickness 18 exceeds the resistance 66 of the substrate 10 to damage from the laser beam 48, the line focus 46 of the laser beam 48 damages the substrate 10 throughout that portion of the thickness 18. In contrast, when the resistance 66 of the substrate 10 to damage from the laser beam 48 exceeds the intensity 60 of the line focus 46, the line focus 46 of the laser beam 48 does not damage the substrate 10 throughout that portion of the thickness 18.

In embodiments, such as that illustrated at FIG. 6A, the intensity 60 of the line focus 46 of the laser beam 48 is sufficient to damage the substrate 10 throughout a first damaged portion 68 into the thickness 18 of the substrate 10 contiguous with the first primary surface 14 of the substrate 10. In addition, the intensity 60 of the line focus 46 of the laser beam 48 is sufficient to damage the substrate 10 throughout a second damaged portion 70 into the thickness 18 of the substrate 10 contiguous with the second primary surface 16 of the substrate 10. However, the intensity 60 of the line focus 46 of the laser beam 48 is insufficient to damage the substrate 10 throughout a non-damaged portion 72 of the thickness 18 that is disposed between the first damaged portion 68 and the second damaged portion 70. The first damaged portion 68 and the second damaged portion 70 may have a diameter of less than 1 μm, such as less than 500 nm, or less than 300 nm, or 300 nm to 1 μm, 300 nm to 500 nm, or 500 nm to 1 μm. At the non-damaged portion 72, the laser beam did not ionize, break molecular bonds within, or vaporize the substrate 10.

In embodiments, the laser 64 is a picosecond laser 64 that produces the laser beam 48 in a burst of pulses. In embodiments, one burst of less than 5 pulses generates both the first damaged portion 68 and the second damaged portion 70. Each pulse has a duration of 100 picoseconds or less (for example, 0.1 picosecond, 5 picoseconds, 10 picoseconds, 15 picoseconds, 18 picoseconds, 20 picoseconds, 22 picoseconds, 25 picoseconds, 30 picoseconds, 50 picoseconds, 75 picoseconds, 100 picoseconds, or any duration between any two of those durations). The intensity 60 of each pulse within the burst may not be equal to that of other pulses within the burst, and the intensity 60 distribution of the multiple pulses within a burst often follows an exponential decay in time. A duration of 1 nanosecond to 50 nanoseconds separates individual pulses within the burst of pulses. The duration can be 10 nanoseconds to 30 nanoseconds, or about 20 nanoseconds. For a given laser 64, the duration between pulses is relatively uniform (±10%). The duration between each burst of pulses is longer (e.g., 1 to 10 microseconds, or 3 to 8 microseconds).

In embodiments, such as that illustrated at FIG. 6A, the intensity 60 of the line focus 46 is not substantially uniform and varies as a function of position within the thickness 18 of the substrate 10. In such a non-uniform density distribution, the intensity 60 of the line focus 46 increases in intensity 60 to the maximum 62 within the thickness 18 of the substrate 10 and then decreases away from the maximum 62, along the path of the laser beam 48. The maximum 62 of the intensity 60 is insufficient to damage the substrate 10 throughout the non-damaged portion 72 of the substrate 10, because the resistance 66 of the substrate 10 to the line focus 46 is greatest near the center of the thickness 18. However, because the resistance 66 of the substrate 10 to damage from the line focus 46 is at a minimum throughout the thickness 18 contiguous with and adjacent to the first primary surface 14 and the second primary surface 16, the intensity 60 of the line focus 46 is sufficient to damage the substrate 10 throughout the first damaged portion 68 contiguous with the first primary surface 14 and the second damaged portion 70 contiguous with the second primary surface 16.

In embodiments, to generate the line focus 46 with an intensity 60 that is not substantially uniform, referring now to FIG. 6B, the laser 64 propagates the laser beam 48 in collimated form and with a Gaussian profile. The laser beam 48 with the Gaussian profile transmits through an axicon 74 (i.e., a lens component with one conical surface 76). The laser beam 48 exits the axicon 74 forming a preliminary line focus 46′ situated directly adjacent to the conical surface 76. A reimaging optical system 78 then reimages the preliminary line focus 46′ as the line focus 46 extending through the substrate 10. The reimaging optical system 78 comprises two optical components—a first optical component 80 having a focal length F1, and a second optical component 82 having focal length F2. A distance F1+F2 separates the first optical component 80 and the second optical component 82. The re-imaged line focus 46 is spaced from an exit surface 84 of the reimaging optical system 78 such that the line focus 46 is not formed directly adjacent to the second optical component 82.

The laser beam 48 leaving the reimaging optical system 78 has a Gauss-Bessel profile, which has a cross section (radial profile) such as that illustrated at FIG. 6C. A center portion 86 of the laser beam 48 shown in the figure corresponds to the line focus 46, and rings 88 around the center portion 86 correspond to optical intensities (beams) converging towards the center of the optical axis 54 further into (or beyond) the thickness 18 of the substrate 10. The center portion 86 of the line focus 46 has a radius 90 (and thus a diameter of twice the radius 90). The radius 90 is preferably as small as possible.

Referring now to FIG. 6D, the profile of the peak intensity 60 along the optical axis 54 of the line focus 46 that the laser beam 48 with the Gauss-Bessel profile forms is non-uniform. The term “peak intensity” here is used to describe the maximum of the intensity 60 observed in a cross-sectional profile of the laser beam 48, where the cross-sectional plane is transverse to the propagation direction of the laser beam 48 (i.e., transverse to the optical axis 54) evaluated at one given location along that direction. The maximum of the intensity 60 will typically be proportional to the amount of energy contained within the central portion 86 of the laser beam 48 at a given location along the propagation direction. The graph reproduced as FIG. 6D illustrates, pursuant to a model, the peak intensity 60 profile of a typical Gauss-Bessel beam (along the beam propagation direction). More specifically, the graph plots the modeled peak intensity 60 profile as a function of distance along the optical axis 54 overlapping with the line focus 46 for the laser beam 48 having the Gauss-Bessel profile generated by the reimaging optical system 78 illustrated at FIG. 6A. The length 52 of the line focus 46, as mentioned, corresponds to the distance along the optical axis 54 between the beginning 56 and the end 58 where the intensity is at least 50 percent of the maximum 62 peak intensity 60 (i.e., at least 0.5 lₘₐₓ). The peak intensity 60 curve illustrates, for example, that the beginning 56 and the end 58 of the line focus 46, between which the peak intensity 60 is at least 50% of the maximum intensity 62, is at a distance of about 0.3 and about 1.6 arbitrary units away from the exit surface 84 of the second optical component 82. The maximum intensity 62 of 1.0 arbitrary units occurs at a distance of about 0.8 arbitrary units along the optical axis 54 away from the exit surface 84 of the second optical component 82.

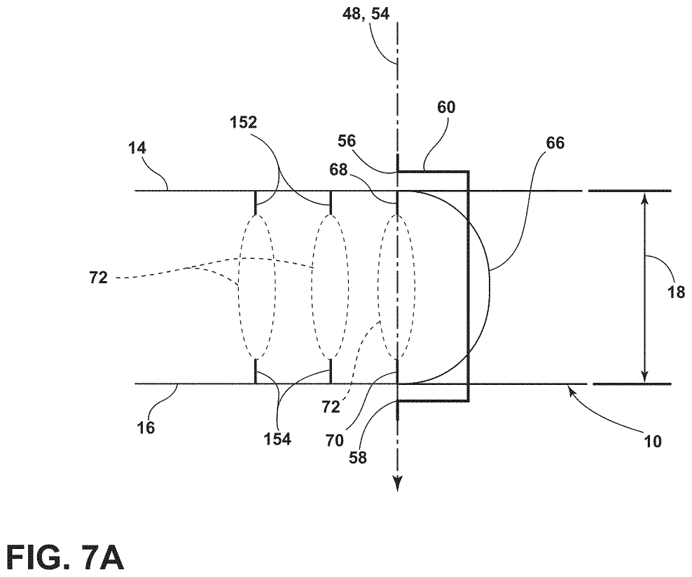

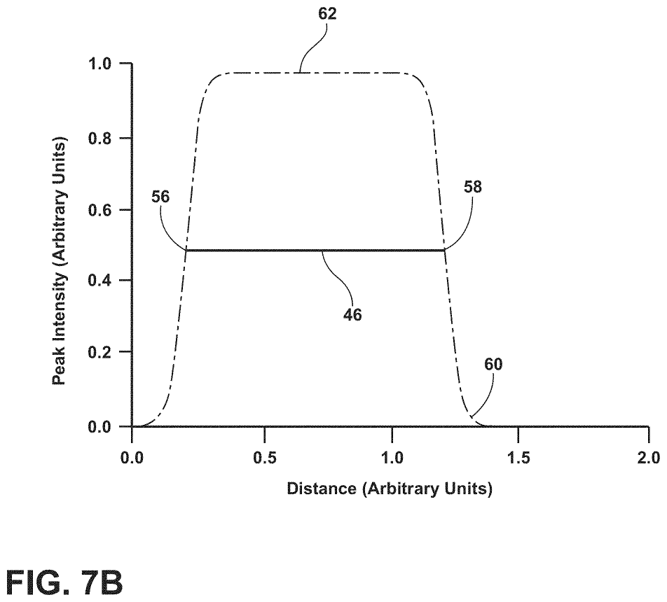

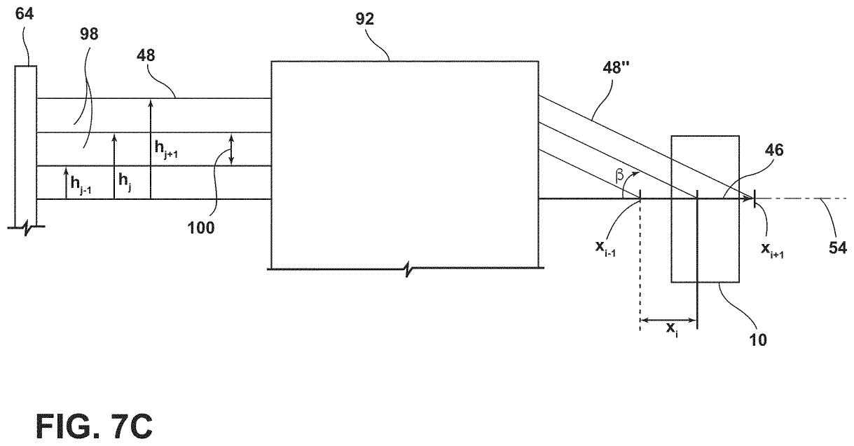

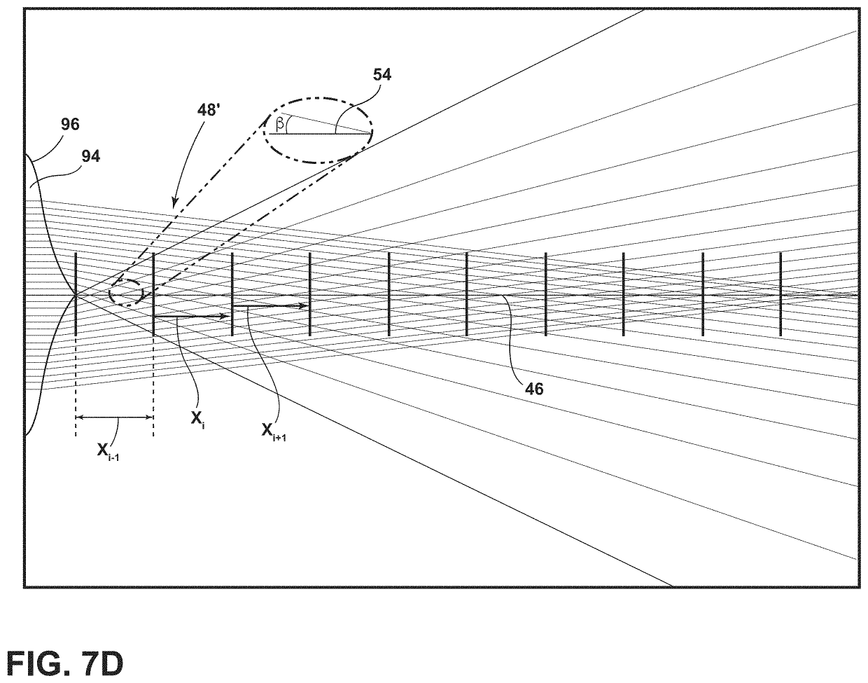

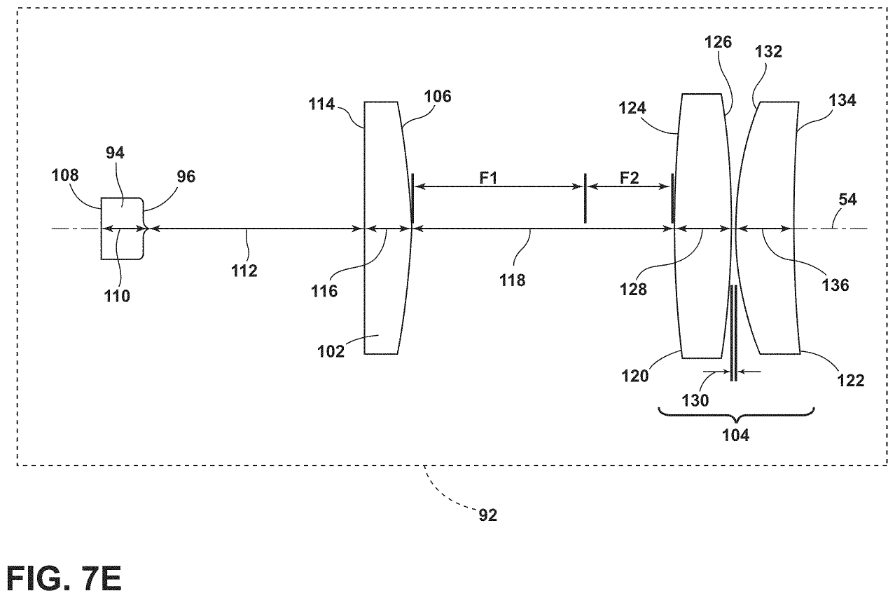

In other embodiments, such as that illustrated at FIG. 7A, the intensity 60 of the line focus 46 that encompasses the thickness 18 of the substrate 10 is substantially uniform. A graph of a substantially uniform peak intensity 60 distribution is reproduced at FIG. 7B. The intensity 60 of the line focus 46 that encompasses the thickness 18 of the substrate 10 is substantially uniform when the peak intensity 60 of the line focus 46 overlapping with the substrate 10 varies by less than 25% relative to the maximum 62 of the peak intensity 60. In embodiments, the peak intensity 60 of the line focus 46 overlapping with the substrate 10 varies by less than 15%, by less than 10%, or by less than 5% relative to the maximum 62.

To generate a line focus 46 that is substantially uniform, an optical system 92 illustrated at FIGS. 7C-7E can be utilized. The laser 64 generates the laser beam 48, which has a Gaussian profile. The laser beam 48 is input into the optical system 92. The optical system 92 is similar to that illustrated at FIG. 6B. However, the optical system 92 includes a modified axicon 94 with an aspheric exit surface 96 instead of the axicon 74 having the conical surface 76.

The laser beam 48 with the Gaussian profile has an energy distribution that can be conceptually subdivided into annular rings 98 of equal intensity 60 (but not necessarily equal width 100). Each of the rings 98 corresponds to a height (hᵢ), where i is a number of 1 to N. In embodiments, N is less than 100, such as 5 to 20. The height hᵢ of each ring 98 is chosen or calculated so that the intensity contained in any ring 98 between two adjacent rings 98 (i.e., rings with ray height hᵢ₋₁ and hᵢ₊₁) is constant.

As mentioned, the optical system 92 includes the axicon 94 with the aspheric exit surface 96. As illustrated in FIG. 7D, the aspheric exit surface 96 of the axicon 94 is not a typical conical surface 76 like with the axicon 74 that has a constant slope (such as in FIG. 6B), but instead has a more complex aspheric profile such that the slope of the aspheric exit surface 96 varies as a function of radial height. Different rays of the laser beam 48 impinging at the aspheric exit surface 96 each encounter a slightly differently sloped surface. The variable slope of the aspheric exit surface 96 produces a modified laser beam 48′ having a substantially uniform peak intensity 60 along the line focus 46. The aspheric exit surface 96 of the axicon 94 bends the rays of the input laser beam 48 having the Gaussian profile to converge towards the line focus 46 so that each segment xᵢ, xᵢ₊₁, etc., of the length 52 of the line focus 46, which correspond to particular rings 98 of equal intensity and having the particular height hᵢ is both substantially equal in length (for example, to a tolerance of ±15%, ±10%, ±5%, or less) and has substantially the same peak intensity 60.

The aspheric exit surface 96 of the axicon 94 can be designed, for example, by starting with the axicon 74 similar to that shown in FIG. 6B having the conical surface 76, and then optimizing the conical surface 76 (via a commercial lens design program) by varying the aspheric coefficients of the exit surface 76 while specifying where the specific rays having specified ray height hᵢ should intersect the optical axis 54. An alternative solution is to trace the rays crossing the points xᵢ, xᵢ₊₁ backwards and calculate where these rays should intersect the aspheric exit surface 96 to correspond to the ray heights hᵢ, hᵢ₊₁, etc., on the input side of the axicon 74. The points of intersection will define the aspheric exit surface 96.

To achieve the line focus 46 having substantially uniform intensity 60 along the length 52, each ray forming the line focus 46 should also intersect the optical axis 54 at substantially the same angle β, as illustrated at FIG. 7C. That is, all rays converging to form the line focus 46 converge at angles β that are within ±15% of each other (such as are within ±10%, or within ±5%, of each other). However, as illustrated in FIG. 7D, the angle β at which each ray of the modified laser beam 48′ forming the line focus 46 is not substantially the same exiting the axicon 74 alone. Unless the optical system 92 corrects the differing ray angles β of the converging rays of the modified laser beam 48′ forming the line focus 46 exiting the axicon 74, the resultant line focus 46 will not have a substantially constant diameter.

To rectify this, in reference to FIG. 7E, in embodiments, the optical system 92 further comprises a first optical component 102 and a second optical component 104, in sequence along the optical axis 54 that further modifies the modified laser beam 48′ exiting the axicon 74 into modified laser beam 48″. The first optical component 102 has an aspheric exit surface 106, as well. The second optical component 104 does not have an aspheric surface and has a different focal length F2 that changes the magnification of the line focus 46. The resulting modified laser beam 48″ exiting the second optical component 104 forms the line focus 46 interacting with the substrate 10, with each of the rays of the modified laser beam 48″ crossing the optical axis 54 at a substantially constant angle β.

The optical system 92 thus modifies the input laser beam 48 having the Gaussian profile into the modified laser beam 48″ having the line focus 46. In doing so, the optical system 92 images the energy within each of the annular rings 98 of equal intensity incoming into the optical system 92 into segments of the line focus 46 having the same or substantially the same length Xᵢ. This condition creates the line focus 46 having a substantially constant peak intensity 60 along at least 90% of the length 52 of the line focus 46. In embodiments, the lengths Xᵢ corresponding to the annular rings 98 of the same intensity of the incoming laser beam 48 deviate by 15% percent or less (such as 10% or less, or 0 to 5%). For example, in the embodiment of FIG. 7C, the lengths Xᵢ within the line focus 46 formed by the optical system 92 are all equal to one another.

In addition, in modifying the incoming laser beam 48 into the modified laser beam 48″ having the line focus 46, the optical system 92 images the rays in the modified laser beam 48″ to have converging ray angles β intersecting the optical axis 54 that are substantially equal to one another. This condition helps to give the line focus 46 of the modified laser beam 48″ a substantially constant diameter for at least 90% of the length 52 of the line focus 46. Variance in the diameter along the length 52 of the line focus 46 would cause the intensity 60 to vary as well. In embodiments, for any given cross-section that includes the center of the line focus 46, the converging ray angle β corresponding to the ray height hᵢ varies by 20% or less than the converging ray angle β corresponding to the ray height hᵢ₋₁. In embodiments, the variance is less than 15%, less than 10%, less than 7%, less than 5%, or 3% to 10%.

In a specific example for the axicon 94, the first optical component 102, and the second optical component 104 of the optical system 92 of FIGS. 7C-7E have the following geometry. The axicon 94 has an entrance surface 108 that is planar and orthogonal to the optical axis 54. A thickness 110 of 4.7 mm separates the entrance surface 108 from the aspheric exit surface 96. The axicon 94 has a refractive index of 1.4745. The aspheric exit surface 96 of the axicon 94 is described by the following equation:

z′=(cr²/1+(1−(1+k)c²r²)^{1/2}(a₁r+a₂r²+a₃r³+a₄r⁴+a₅r⁵+a₆r⁶+a₇r⁷+a₈r⁸+a₉r⁹+a₁₀r¹⁰+a₁₁r¹¹+a₁₂r¹²)

where z′ is the surface sag, r is the height of the surface from the optical axis 54 in radial direction (e.g., x or y height, depending on surface cross-section), c is the surface curvature (i.e., cᵢ=1/Rᵢ), Rᵢ is the radius of curvature, k is the conic constant, and coefficients aᵢ are the first to the 12th order aspheric coefficients describing the surface. Particularly, a₁=−0.085274788; a₂=0.065748845; a₃=0.077574995; a₄=−0.054148636; a₅=0.022077021; a₆=−0.0054987472; a₇=0.0006682955; and the aspheric coefficients a₈ through a₁₂ each equal 0. The conic constant, k, equals 0. The modified axicon has an Abbe Number of 81.6078.

A distance 112 of 133.115 mm separates the axicon 94 from the first optical component 102. The first optical component 102 includes an entrance surface 114 that is planar and orthogonal to the optical axis 54. The exit surface 106 of the first optical component 102, as mentioned, is aspheric, with a radius of curvature of −64.902 mm, a conic constant k of 4.518096, and coefficients a₁ through a₁₂ each equal 0. The first optical component 102 has a thickness 116 of 4.7 mm. The first optical component 102 has a refractive index of 1.4745. The first optical component 102 has an Abbe Number of 81.6078. The first optical component 102 has a focal point F1 of 125 mm.

A distance 118 of 157.894 mm separates the first optical component 102 from the second optical component 104. The second optical component 104 is a doublet of a lens 120 and a lens 122. The lens 120 includes an entrance surface 124 that has a radius of curvature of 76.902 mm. The lens 120 includes an exit surface 126 that has a radius of curvature of −128.180. The lens 120 has a thickness 128 of 6 mm. A distance 130 of 0.5 mm separates the lens 120 from the lens 122. The lens 122 includes an entrance surface 132 that has a radius of curvature of 32.081 mm. The lens 122 includes an exit surface 134 that has a radius of curvature of 95.431. The lens 122 has a thickness 136 of 6 mm. Both the lens 120 and the lens 122 have a refractive index of 1.6200 and an Abbe Number of 36.3655. The second optical component 104 has a focal point F2 of 40 mm. The line focus 46 begins 2.73 mm from the second optical component 104.

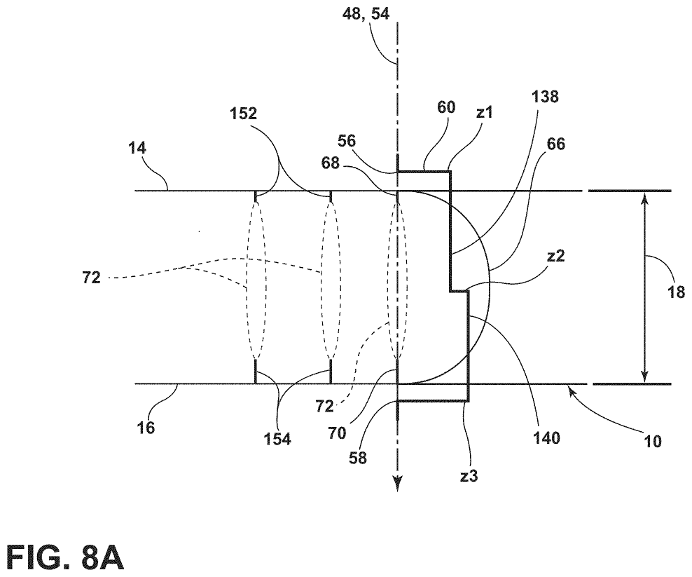

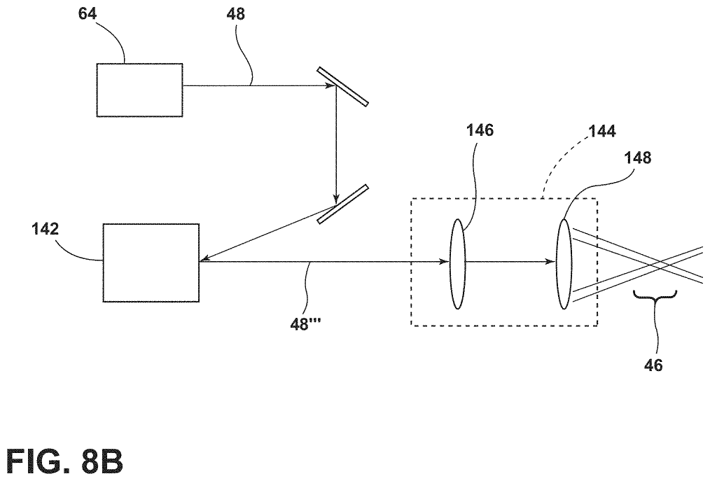

In still other embodiments, such as that illustrated at FIG. 8A, the intensity 60 of the line focus 46 is substantially uniform throughout a first intensity region 138 that forms the first damaged portion 68. The first intensity region 138 encompasses the first primary surface 14 of the substrate 10 and a portion of the thickness 18 of the substrate 10. In addition, the intensity 60 of the line focus 46 is substantially uniform throughout a second intensity region 140 that forms the second damaged portion 70. The second intensity region 140 encompasses the second primary surface 16 of the substrate 10 and a portion of the thickness 18 of the substrate 10. The intensity 60 of the line focus 46 at the first intensity region 138 is different than the intensity 60 of the line focus 46 of the second intensity region 140. In embodiments, the intensity 60 of the line focus 46 throughout the first intensity region 138 is greater than the intensity 60 of the line focus 46 throughout the second intensity region 140. In other embodiments, the intensity 60 of the line focus 46 throughout the first intensity region 138 is less than the intensity 60 of the line focus 46 throughout the second intensity region 140.

Referring now to FIG. 8B, to generate the line focus 46 that has the intensity 60 that is substantially uniform throughout the first intensity region 138 and the second intensity region 140 (with the intensity 60 of the line focus 46 at the first intensity region 138 being different than the intensity 60 of the line focus 46 at the second intensity region 140), a spatial light modulator 142 can be utilized to manipulate the laser beam 48 emitted by the laser 64 having the Gaussian profile into a modified laser beam 48′″. The modified laser beam 48′″ enters a reimaging optical system 144 to form the line focus 46. The reimaging optical system 144 includes a first optical component 146 that selects out only the first order of diffraction of the modified laser beam 48′″ exiting the spatial light modulator 142. The reimaging optical system 144 further includes a second optical component 148 that focuses the first order of diffraction into the line focus 46.

In embodiments, the spatial light modulator 142 is phase modulating only. To utilize the phase-only spatial light modulator 142, the desired profile of the intensity 60 l(z) of the line focus 46 as a function of position z along the length 52 of the line focus 46 is determined and mathematically described according to the following equation:

$$I ( z ) = \{ \begin{matrix}{I}_{first region} & if {z}_{1} \leq z \leq {z}_{2} \\ {I}_{second region} & if {z}_{2} \leq z \leq {z}_{3}\end{matrix}$$

where z₁ and z₂ are the beginning and the end, respectively, of the first intensity region 138, and z₂ and z₃ are the beginning and the end, respectively, of the second intensity region 140. The spatial spectrum S in the first order of diffraction of the manipulated laser beam 48′″ leaving the spatial light modulator 142 providing the desired profile of the intensity 60 l(z) of the line focus 46 can be determined according to the following equation:

$$S ( \sqrt{{k}_{0}^{2} - {k}_{z}^{2}} , z = 0 ) = \frac{1}{{k}_{z}} {\int }_{0}^{+ ∞} \sqrt{I ( z )} exp [ i ( {k}_{z 0} - {k}_{z} ) z ] d z$$

where, k₀ is the wave vector of the manipulated laser beam 48″, k_{z} is the longitudinal spatial frequency of the manipulated laser beam 48′″, and k_{z0} is the longitudinal Bessel frequency and is equal to k₀ cos(Θ), where Θ is the cone angle (i.e., the angle of the wave vector relative to the optical axis 54). The optical field E(r, z=0) for the line focus 46 is then determined according to the following equation:

$$E ( r , z = 0 ) = \frac{1}{2 π} {\int }_{0}^{+ ∞} S ( {k}_{r} , z = 0 ) {J}_{0} ( {k}_{r} r ) {k}_{r} d {k}_{r}$$

where, r is the transverse radial coordinate, kᵣ is the transverse spatial frequency corresponding to the transverse radial coordinate r, J₀ is an infinity of zeroth order Bessel functions of the first kind, and S(kᵣ,z=0) is the amplitude of the spatial spectrum S.

A phase mask that the spatial light modulator 142 utilizes is then designed to provide the desired optical field E(r, z=0) from the incident laser beam 48. The phase mask can be expressed by the following equation:

ψ(m,n)=M(m,n)mod[F(m,n)+Φ_{ref}(m,n),2π]

where, m and n are pixel locations of the spatial light modulator, M is a normalized expression of amplitude having a value of 0 to 1, “mod” is the modulo function, F is an expression of phase, and Φ_{ref} is a linear phase ramp used to separate different diffraction orders. In turn, M and F, can be determined from the following equations:

$$M ( m , n ) = 1 + \frac{sin {c}^{- 1} ( \frac{A ( m , n )}{{A}_{inc} ( m , n )} )}{π}$$

F(m,n)=Φ(m,n)−πM(m,n)

where sinc⁻¹ is the inverse of the sinc function, A is the spatial amplitude of the desired optical field E(r, z=0), A_{inc} is amplitude of the incident laser beam 48, and Φ is the spatial phase of the desired optical field E(r, z=0). The spatial light modulator 142 is then operated with the determined phase mask and reflects the desired optical field from the incident laser beam 48—in this instance, having the desired intensities 60 l for the first intensity region 138 and the second intensity region 140.

At a step 150, the method 12 further comprises repeating the step 44 while the substrate 10 is translated relative to the laser beam 48. More specifically, in embodiments, the first primary surface 14 of the glass substrate 10 is translated laterally relative to the optical axis 54 of the laser beam 48. For example, in embodiments, the substrate 10 is positioned on a translating table (not shown) such that it may be translated in two dimensions (x and y) or three dimensions (x, y, and z). Such translating tables can translate the substrate 10 at an average speed of about 0.5 meters per second. Additionally or alternatively, the laser 64 is coupled to a translation mechanism such that the laser beam 48 that the laser 64 generates is translated with respect to the substrate 10. The result is the formation of a series 152 of first damaged portions 68 into the thickness 18 of the substrate 10 contiguous with the first primary surface 14, and a series 154 of second damaged portions 70 into the thickness 18 of the substrate 10 contiguous with the second primary surface 16.

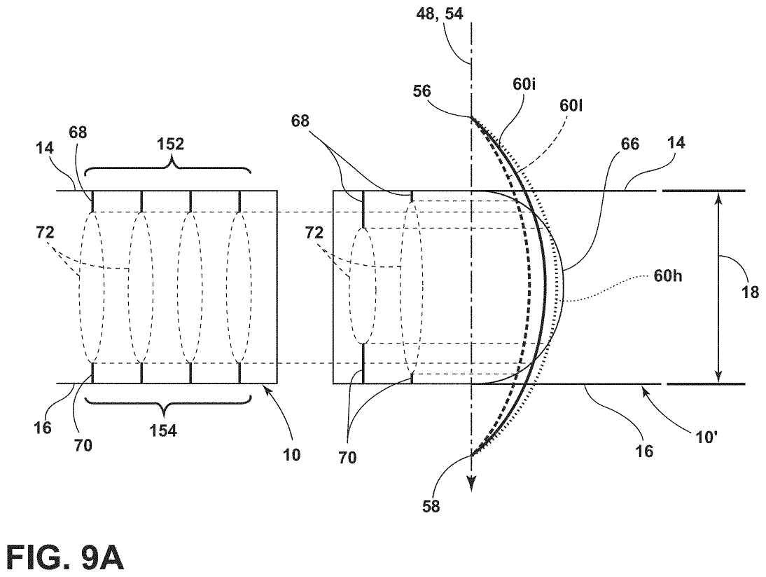

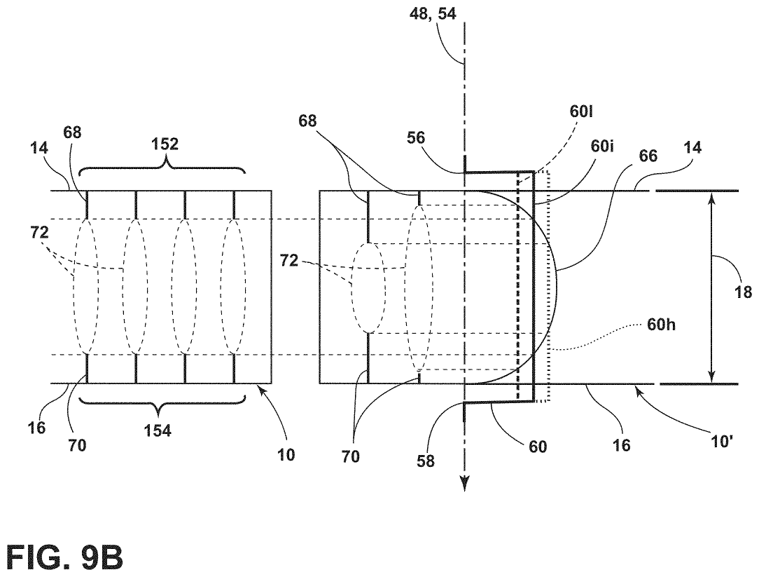

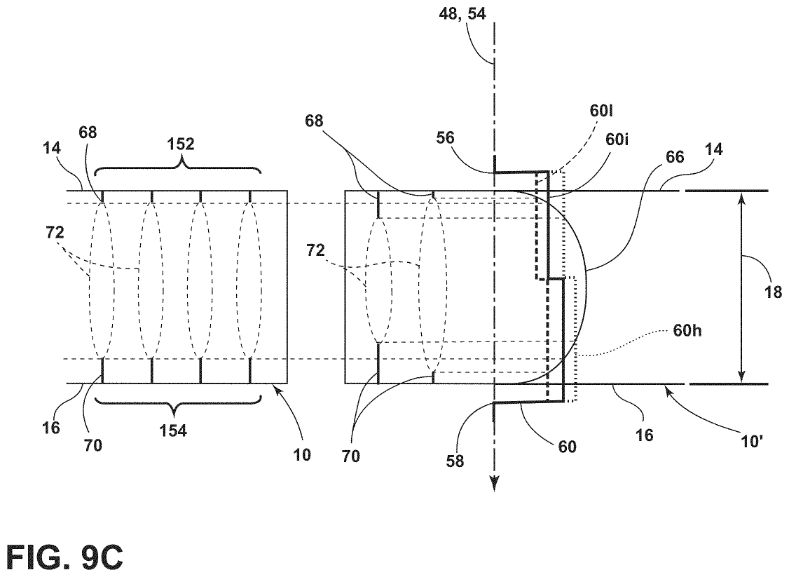

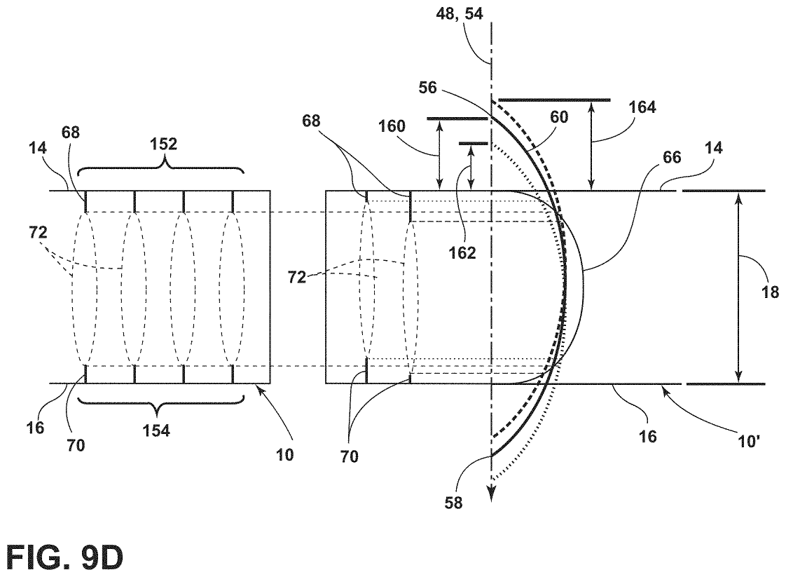

Referring now to FIGS. 9A-9C, in embodiments, at a step 156, the method 12 further comprises repeating steps 44 and 150 of the method 12 but with a second substrate 10′ and with the intensity 60 of the line focus 46 being altered compared to the intensity 60 of the line focus 46 utilized for the substrate 10. The step 156 is performed after the steps 44 and 150 of forming the series 152 of first damaged portions 68 and the series 154 of second damaged portions 70 into the substrate 10 at an initial intensity 60i of the line focus 46. In embodiments, for step 156, altering the intensity 60 of the line focus 46 includes lowering the intensity 60, such as from the initial intensity 60i to a lower intensity 60l. Assuming that the resistance 66 of the second substrate 10′ to the intensity 60 of the line focus 46 is the same as the resistance 66 of the substrate 10 to the line focus 46, lowering the intensity 60 from the initial intensity 60i to the lower intensity 60l decreases the extent to which the first damaged portion 68 and the second damaged portion 70 extend into the thickness 18 of the second substrate 10′ compared to the substrate 10 and, thus, increases the size of the non-damaged portion 72 between the first damaged portion 68 and the second damaged portion 70 in the second substrate 10′ compared to the substrate 10.

In other embodiments, for step 156, the intensity 60 of the line focus 46 includes increasing the intensity 60 of the line focus 46, such as from the initial intensity 60i to a higher intensity 60h. Assuming that the resistance 66 of the substrate 10 to the intensity of the line focus 46 is the same as the resistance 66 of the substrate 10 to the line focus 46, increasing the intensity 60 to the higher intensity 60h from the initial intensity 60i increases the extent to which the first damaged portion 68 and the second damaged portion 70 extend into the thickness 18 of the second substrate 10′ compared to the substrate 10 and, thus, decreases the size of the non-damaged portion 72 between the first damaged portion 68 and the second damaged portion 70 in the second substrate 10′ compared to the substrate 10. FIGS. 9A-9C illustrate the second substrate 10′ with the first damaged portions 68 and the second damaged portions 70 generated from both the higher intensity 60h and the lower intensity 60i. However, this is for ease of comprehension. In actuality, the second substrate 10′ will include the first damaged portions 68 and the second damaged portions 70 generated from either the higher intensity 60h or the lower intensity 60l but not both.

Referring now to FIG. 9D, in embodiments, at a step 158, the method 12 further comprises repeating steps 44 and 150 of the method 12 but with the second substrate 10′ and with a distance 160 between the first primary surface 14 of the second substrate 10′ and the beginning 56 of the line focus 46 along the optical axis 54 of the line focus 46 being altered compared to the distance 160 between the first primary surface 14 of the substrate 10 and the beginning 56 of the line focus 46 along the optical axis 54. The step 158 is performed after the steps 44 and 150 of forming the series 152 of first damaged portions 68 and the series 154 of second damaged portions 70 into the substrate 10 using the distance 160 between the first primary surface 14 of the substrate 10 and the beginning 56 of the line focus 46. In embodiments, for step 158, altering the distance 160 includes shortening from the distance 160 to a shorter distance 162. Assuming that the resistance 66 of the second substrate 10′ to the intensity 60 of the line focus 46 is the same as the resistance 66 of the substrate 10 to the line focus 46, shortening to the shorter distance 162 decreases the extent to which the first damaged portion 68 extends into the thickness 18 of the second substrate 10′ compared to the substrate 10 and increases the extent to which the second damaged portion 70 extends into the thickness 18 of the second substrate 10′ compared to the substrate 10.

In other embodiments, for step 158, altering the distance 160 includes lengthening from the distance 160 to a longer distance 164. Assuming that the resistance 66 of the second substrate 10′ to the intensity 60 of the line focus 46 is the same as the resistance 66 of the substrate 10 to the line focus 46, lengthening to the longer distance 164 increases the extent to which the first damaged portion 68 extends into the thickness 18 of the substrate 10 and decreases the extent to which the second damaged portion 70 extends into the thickness 18 of the substrate 10.

In embodiments, the method 12 includes both (i) the step 156 with the altered intensity 60 of the line focus 46 for the second substrate 10′ and (ii) the step 158 with the altered shortened distance 162 or lengthened distance 164 between the first primary surface 14 of the second substrate 10′ and the beginning 56 of the line focus 46.

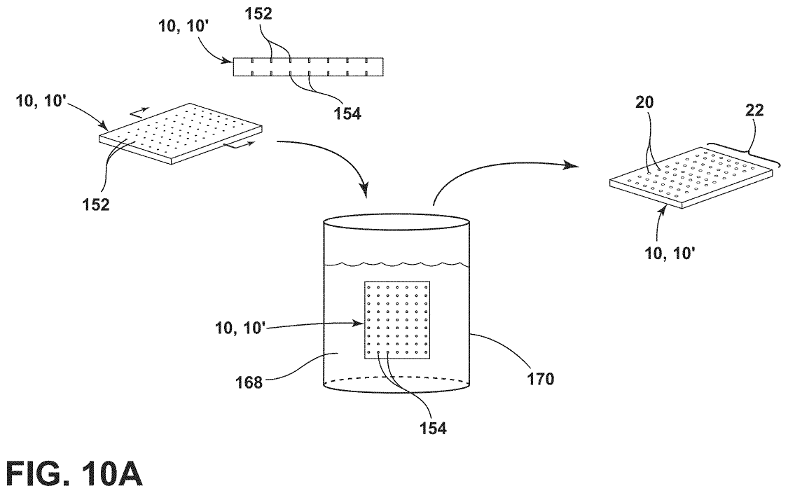

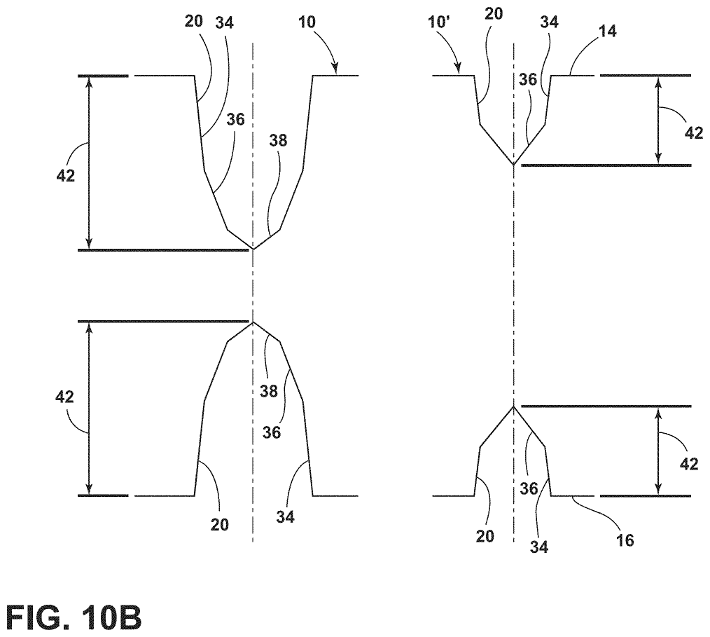

Referring now to FIG. 10A, at a step 166, the method 12 further comprises contacting the series 152 of first damaged portions 68 and the series 154 of second damaged portions 70 of the substrate 10 (and the second substrate 10′, if utilized) with an etchant 168. In embodiments, an etching solution tank 170 contains the etchant 168, and the substrate 10 (and the second substrate 10′, if utilized) is submerged into the etchant 168. The etching solution tank 170 can be formed from an acid-resistant material, such as a plastic-like polypropylene or high density polyethylene.

In some embodiments, the etchant 168 is an aqueous solution including deionized water, a primary acid, and a secondary acid. The primary acid may be hydrofluoric acid and the secondary acid may be nitric acid, hydrochloric acid, or sulfuric acid. Thus, in embodiments, the etchant 168 is an aqueous solution comprising hydrofluoric acid and hydrochloric acid. In some embodiments, the etchant 168 includes a primary acid other than hydrofluoric acid and/or a secondary acid other than nitric acid, hydrochloric acid, or sulfuric acid. Furthermore, in embodiments, the etchant 168 includes only a primary acid. In embodiments, the etchant 168 comprises hydrofluoric acid. In other embodiments, the etchant 168 includes different proportions of the primary acid, the secondary acid, and deionized water. In some embodiments, the etchant 168 includes a surfactant, such as 5-10 mL of a commercially available surfactant. The surfactant increases the wetting ability of the series 152 of first damaged portions 68 and series 154 of second damaged portions 70. In embodiments, the etchant 168 includes 20% by volume of a primary acid (e.g., hydrofluoric acid), 10% by volume of a secondary acid (e.g., nitric acid), and 70% by volume of deionized water. Other exemplary aqueous etchants 168 comprise (i) 10% by volume hydrofluoric acid with 15% by volume nitric acid, (ii) 5% by volume hydrofluoric acid with 7.5% by volume nitric acid, and (iii) 2.5% by volume hydrofluoric acid with 3.75% by volume nitric acid. The etchant 168 can have a temperature of approximately room temperature (e.g., 23° C. to 27° C.).

In embodiments, the etchant 168 is a hydroxide material. For example, in embodiments, the etchant 168 is at least one of sodium hydroxide, potassium hydroxide and tetramethylammonium hydroxide, and in specific embodiments, these materials are formed in an aqueous mixture with at least one of a diol and an alcohol. In embodiments, the etchant 168 has a hydroxide concentration of at least 0.5 M. In embodiments, the etchant 168 is sodium hydroxide or potassium hydroxide, or a combination of the two, having a concentration between 1 M and 19.5 M. In embodiments, the etchant 168 is maintained at a temperature of greater than 60° C. during the etching step, such as 60 to 175° C., or 60 to 120° C.

Contacting the series 152 of first damaged portions 68 and the series 154 of second damaged portions 70 with the etchant 168 results in the formation of the first series 22 of blind vias 20 into the thickness 18 of the substrate 10 that are open to the first primary surface 14, and the second series 28 of blind vias 20 into the thickness 18 that are open to the second primary surface 16. More specifically, the etchant 168 enters into the series 152 of first damaged portions 86 and the series 154 of second damaged portions 70, removes adjacent substrate 10 to form the first series 22 of blind vias 20 and the second series 28 of blind vias 20, and continues to remove adjacent substrate 10 increasing the diameter of the first series 22 of blind vias 20 and the second series 28 of blind vias 20 until the desired diameter is reached. The substrate 10 is then removed from contacting the etchant 168. This applies equally as well to the second substrate 10′ if utilized.

In embodiments, the substrate 10 (and second substrate 10′, if utilized) is mechanically agitated, such as by moving the substrate 10 up-and-down or side-to-side in the etchant 168 either manually or by machine, during at least a portion of the etching duration to facilitate removal of sludge from the blind vias 20. In embodiments, ultrasonic energy is applied to the etchant 168 or the substrate 10 (or both) while contacting the etchant 168. The application of ultrasonic energy enhances the etching of the substrate 10 and facilitates the formation of the first series 22 of blind vias 20 and the second series 28 of blind vias 20 by facilitating movement of the etchant 168 relative to the substrate 10. The geometry of the first series 22 of blind vias 20 and the second series 28 of blind vias 20 is discussed above.

Referring now to FIG. 10B, in embodiments of the method 12 that include the step 156, the step 158, or both the steps 156 and 158, the blind vias 20 of the first series 22 of blind vias 20 and the second series 28 of blind vias 20 of the substrate 10 have mean depths 42 that are different than the mean depths 42 of the blind vias 20 of the first series 22 of blind vias 20 and the second series 28 of blind vias 20 of the second substrate 10′. For example, in embodiments of the step 156 where the intensity 60 of the line focus 46 was decreased to the lower intensity 60l for the second substrate 10′, the series 152 of first damaged portions 68 and the series 154 of second damaged portions 70 extend less into the thickness 18 of the substrate 10′ than the substrate 10. Consequently, the depths 42 of the blind vias 20 formed from etching the series 152 of first damaged portions 68 and the series 154 of second damaged portions 70 of the second substrate 10′ are shallower than the depths 42 of the blind vias 20 formed from etching the series 152 of first damaged portions 68 and the series 154 of second damaged portions 70 of the substrate 10.

In contrast, in embodiments of the step 156 where the intensity 60 of the line focus 46 was increased to the higher intensity 60h for the second substrate 10′, the series 152 of first damaged portions 68 and the series 154 of second damaged portions 70 formed in the second substrate 10′ extend deeper into the thickness 18 of the substrate 10 than the substrate 10. Consequently, the depths 42 of the blind vias 20 formed from etching the series 152 of first damaged portions 68 and the series 154 of second damaged portions 70 of the second substrate 10′ are deeper than the depths 42 of the blind vias 20 formed from etching the series 152 of first damaged portions 68 and the series 154 of second damaged portions 70 of the substrate 10.

In embodiments of the step 158 where the distance 160 was decreased to the shorter distance 162 for the second substrate 10′, the series 152 of first damaged portions 68 extend less into the thickness 18 of the second substrate 10′ than the substrate 10, and the series 154 of second damaged portions 70 extend more into the thickness 18 of the second substrate 10′ than the substrate 10. Consequently, (i) the depths 42 of the blind vias 20 formed from etching the series 152 of first damaged portions 68 of the second substrate 10′ are shallower than the depths 42 of the blind vias 20 formed from etching the series 152 of first damaged portions 68 of the substrate 10, and (ii) the depths 42 of the blind vias 20 formed from etching the series 154 of second damaged portions 70 of the second substrate 10′ are deeper than the depths 42 of the blind vias 20 formed from etching the series 154 of second damaged portions 70 of the substrate 10.

In contrast, in embodiments of the step 158 where the distance 160 was increased to the longer distance 164 for the second substrate 10, the series 152 of first damaged portions 68 extend more into the thickness 18 of the second substrate 10′ than the substrate 10, and the series 154 of second damaged portions 70 extend less into the thickness 18 of the second substrate 10′ than the substrate 10. Consequently, (i) the depths 42 of the blind vias 20 formed from etching the series 152 of first damaged portions 68 of the second substrate 10′ are deeper than the depths 42 of the blind vias 20 formed from etching the series 152 of first damaged portions 68 of the substrate 10, and (ii) the depths 42 of the blind vias 20 formed from etching the series 154 of second damaged portions 70 of the second substrate 10′ are shallower than the depths 42 of the blind vias 20 formed from etching the series 154 of second damaged portions 70 of the substrate 10.

Etching is a highly parallel process in which all damaged portions 68, 70 are simultaneously enlarged much faster than the non-damaged portions 70. In addition, etching helps to passivate any edges or small cracks within the substrates 10, which increases the overall strength and reliability of the substrates 10. This applies equally as well to the second substrate 10′.

At a step 172, the method 12 further comprises depositing metal 40 within the first series 22 of blind vias 20 and the second series 28 of blind vias 20. The step 172 is sometimes referred to as metallization of the blind vias 20. The metal 40 may be, for example, aluminum, copper, gold, magnesium, nickel, platinum, silver, titanium, tungsten, or alloys thereof. Metallization of the blind vias 20 can include electroplating, electroless plating, physical vapor deposition, or other vapor coating methods, or some combination thereof. In embodiments, the step 172 first includes electroless plating a first metal (e.g., silver), sometimes referred to as a seed layer, onto the interior wall 32 of the blind vias 20, and then electroplating a second metal (e.g., copper) over the first metal to fully metallize the blind vias 20.

In embodiments, the method 10 further includes dividing the substrate 10 along the division 43 into the alpha substrate 10α and the beta substrate 10α. This division can occur just before the step 166 (etching) or after the step 166 and before the step 172 (metallization). When the division occurs before the etching step 166, the alpha substrate 10α includes the series 152 of first damaged portions 68 from the substrate 10, while the beta substrate 10α includes the series 154 of second damaged portions 70 from the substrate 10. The alpha substrate 10α and the beta substrate 10β can then be subjected to the step 166 by contacting the series 152 of first damaged portions 68 and the series 154 of second damaged portions 70 with the etchant 168, thus forming the series 22 of blind vias 20 into the alpha substrate 10α and the series 22 of blind vias 20 into the beta substrate 10β. The etchant 168 can contact the alpha substrate 10α for a different time period than the beta substrate 10β, or the same time period. When the division occurs after the etching step 166, the alpha substrate 10α includes the first series 22 of blind vias 20 from the substrate 10, while the beta substrate 10β includes the second series 28 of blind vias 20 from the substrate 10. The alpha substrate 10α and the beta substrate 10β can then be subjected to the step 172 of metallization either together or separately.

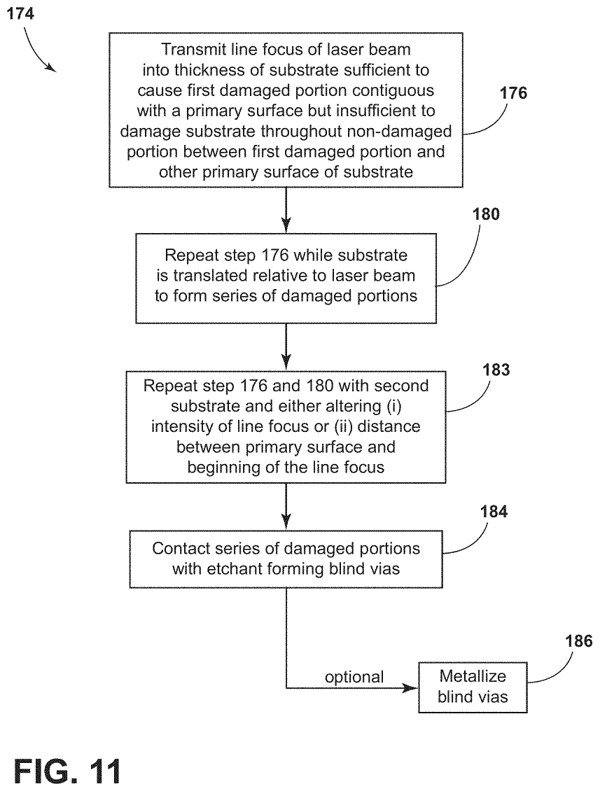

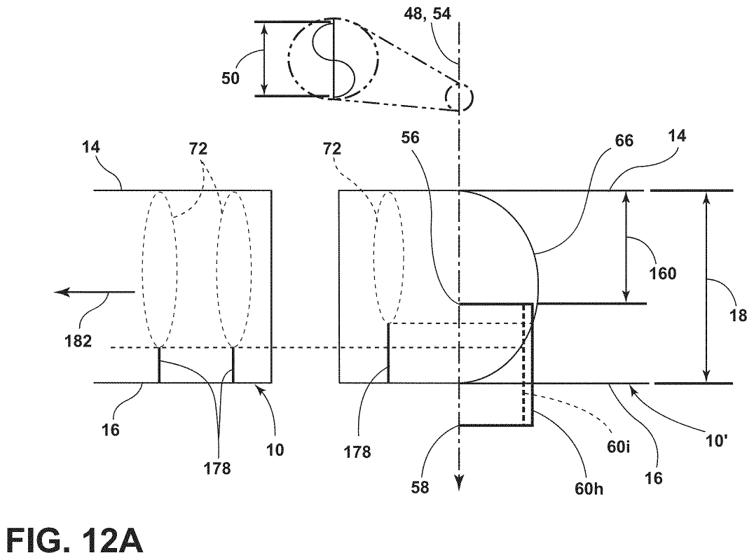

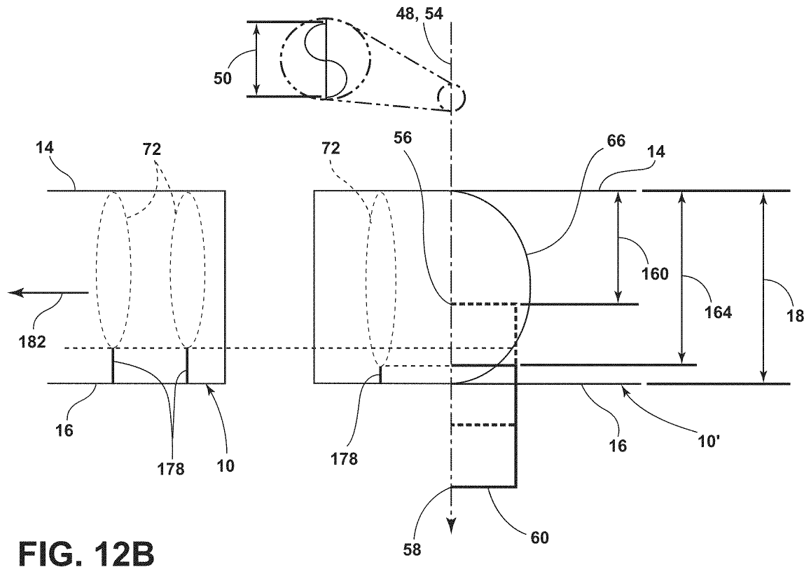

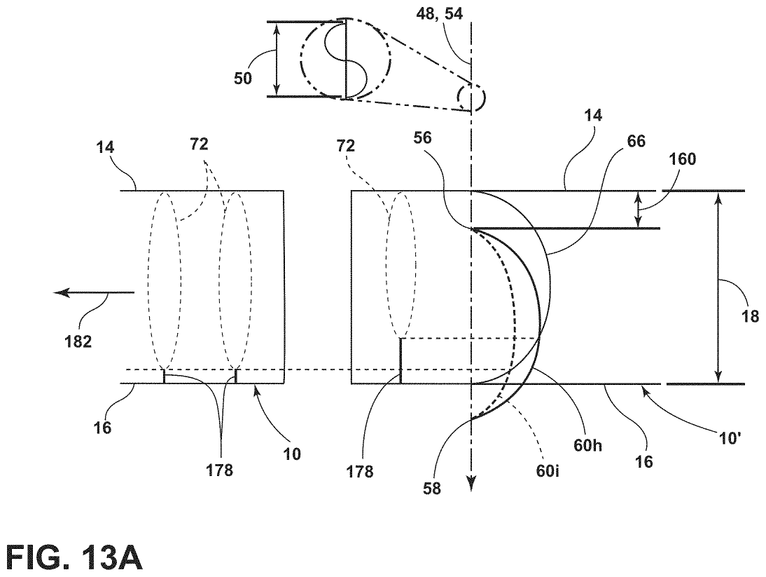

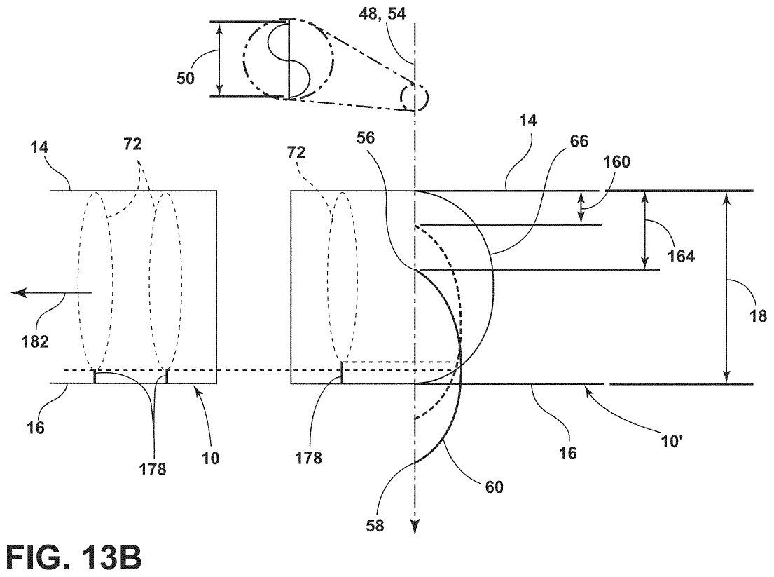

Referring now to FIGS. 11-14, another method 174 of forming blind vias 20 in the substrates 10 and 10′ is herein described. At a step 176, the method 174 includes transmitting the line focus 46 of the laser beam 48 through one of the primary surfaces 14, 16 of the substrate 10 (e.g., the second primary surface 16, as illustrated) and into the thickness 18 of the substrate 10. As with the method 12 above, the laser beam 48 has the wavelength 50, the substrate 10 is transparent to the wavelength 50 of the laser beam 48, and the line focus 46 has the intensity 60 as a function of depth into the thickness 18 of the substrate 10. The intensity 60 of the line focus 46 is sufficient to damage the substrate 10 throughout a damaged portion 178 into the thickness 18 that is contiguous with the primary surface 16 of the substrate 10. As explained above, the substrate 10 has the resistance 66 to the line focus 46 that varies as a function of position through the thickness 18. When the intensity 60 of the line focus 46 overcomes the resistance 66, the line focus 46 damages the substrate 10 and forms the damaged portion 178. When the resistance 66 of the substrate 10 to the line focus 46 is sufficient to withstand the intensity 60 of the line focus 46, the substrate 10 is not damaged leaving a non-damaged portion 72 of the substrate 10 that is disposed between the damaged portion 178 and the other primary surface 14 of the substrate 10. As explained above, in embodiments (such as that illustrated at FIGS. 12A and 12B), the intensity 60 of the line focus 46 is substantially uniform along the optical axis 54. In other embodiments, as discussed (such as that illustrated at FIGS. 13A and 13B), the intensity 60 of the line focus 46 is not substantially uniform along the optical axis 54 and varies as a function of position within the thickness 18 of the substrate 10.

In a step 180, the method 174 further includes repeating step 176 while the substrate 10 is translated 182 (e.g., laterally) relative to the optical axis 54 of the laser beam 48 to form the series of damaged portions 178 into the thickness 18 of the substrate 10 contiguous with the second primary surface 16. The laser beam 48 burst creates one of the damaged portions 178, the substrate 10 is translated 182, and another laser beam 48 burst creates another one of the damaged portions 178. Because of the short time span of each burst, the substrate 10 may be translated 182 continuously.

In a step 183, the method 174 further includes repeating the steps 176 and 180 with the second substrate 10′ and either (i) the intensity 60 of the line focus 46 being altered compared to the substrate 10, or (ii) the distance 160 between the primary surface 14 of the second substrate 10′ and the beginning 56 of the line focus 46 along the optical axis 54 of the line focus 46 being altered compared to the substrate 10.

In embodiments, the step 183 includes repeating the steps 176 and 180 with the second substrate 10′ and the intensity 60 of the line focus 46 being altered compared to the substrate 10. In the scenarios illustrated at FIGS. 12A and 13A, after the line focus 46 at the initial intensity 60i forms the series of damaged portions 178 into the substrate 10 while the substrate 10 is translated 182, the line focus 46 at the higher intensity 60h forms another series of damaged portions 178 into the second substrate 10′. The series of damaged portions 178 of the second substrate 10′ extend further into the thickness 18 of the second substrate 10′ from the second primary surface 16 than the series of damaged portions 178 that extend into the substrate 10. Although not separately illustrated, if the intensity 60 of the line focus 46 for the second substrate 10′ was decreased rather than increased compared to the substrate 10, then the line focus 46 would have created a series of damaged portion 178 that extend less into the thickness 18 of the second substrate 10′ than the series of damaged portions 178 formed into the substrate 10.

In embodiments, the step 183 includes repeating the steps 176 and 180 with the second substrate 10′ and the distance 160 between the primary surface 14 of the second substrate 10′ and the beginning 56 of the line focus 46 along the optical axis 54 of the line focus 46 being altered compared to the substrate 10. In the scenarios illustrated at FIGS. 12B and 13B, after the line focus 46 forms the series of damaged portions 178 into the substrate 10 with the distance 160 between the first primary surface 14 and the beginning 56 of the line focus 46 while the substrate 10 is translated 182, the line focus 46 forms the series of damaged portions 178 into the second substrate 10′ with the longer distance 164 between the first primary surface 14 and the beginning 56 of the line focus 46. For the scenario of FIG. 12B, the series of damaged portions 178 extend less into the thickness 18 of the second substrate 10′ from the second primary surface 16 than the series of damaged portions 178 of the substrate 10. For the scenario of FIG. 13B, the series of damaged portions 178 extend deeper into the thickness 18 of the second substrate 10′ from the second primary surface 16 than the series of damaged portions 178 of the substrate 10.

In embodiments, step 183 includes repeating the steps 176 and 180 with both (i) the intensity 60 of the line focus 46 being altered for the second substrate 10′ compared to the substrate 10 and (ii) the distance 160 between the first primary surface 14 and the beginning 56 of the line focus 46 along the optical axis 54 being altered for the second substrate 10′ compared to the substrate 10.

As discussed, in embodiments, both the substrate 10 and the second substrate 10′ comprise glass, and the laser beam 48 is produced by a picosecond laser 64 in a burst of pulses. A burst of less than 5 pulses generates any single damaged portion 178.

In a step 184, the method 174 further includes contacting the series of damaged portions 178 of the substrate 10 and the second substrate 10′ with the etchant 168 in the manner described above in connection with step 166 of the method 12. Contacting the damaged portions 178 with the etchant 168 forms the series 28 of blind vias 20 into the thickness 18 of the substrate 10 and the second substrate 10′ that are open to the second primary surface 16.

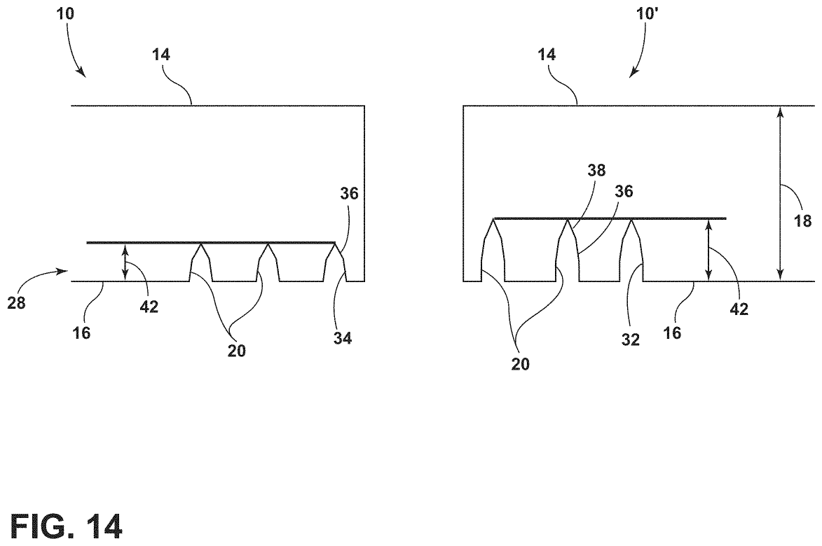

Each of the blind vias 20 has a depth 42. The series 28 of blind vias 20 into the substrate 10 has a mean depth 42. The series 28 of blind vias 20 into the second substrate 10′ has a mean depth 42. As illustrated at FIG. 14, the mean depth 42 of the series 28 of blind vias 20 formed into the substrate 10 is different than the mean depth 42 of the series 28 of blind vias 20 formed into the second substrate 10′. For example, in the circumstances of FIGS. 12A and 13A, where the series of damaged portions 178 formed with the higher intensity 60h into the second substrate 10′ are deeper than the damaged portions 178 formed at the initial intensity 60i into the substrate 10, subsequent etching of those damaged portions 178 of the second substrate 10′ resulted in blind vias 20 that had deeper depth 42 than the depth 42 of the blind vias 20 etched from the damaged portions 178 of the substrate 10 formed with the initial intensity 60i.

By following the method 174, the depths 42 of the blind vias 20 of the substrate 10 deviate from their respective mean depth 42 by less than +/−10%, +/−9%, +/−8%, +/−7%, +/−6%, +/−5%, +/−4%, +/−3%, +/−2%, +/−1%, or +/−<1%. The depths 42 of the blind vias 20 of the second substrate 10′ deviate from their respective mean depth 42 by less than +/−10%, +/−9%, +/−8%, +/−7%, +/−6%, +/−5%, +/−4%, +/−3%, +/−2%, +/−1%, or +/−<1%.

In embodiments, the method 174 further includes a step 186 of metallizing the blind vias 20, as discussed above in connection with step 172 of method 12, to deposit the metal 40 within the blind vias 20 of both the substrate 10 and the second substrate 10′.

### EXAMPLES

Example 1. For Example 1, three samples (Sample 1, Sample 2, Sample 3) of a substrate were selected, each sample having a thickness of 360 μm, a length of 50 mm and a width of 50 mm. The substrate had a composition of high purity fused silica. A Coherent Hyper-Rapid-50 picosecond laser was utilized to generate a laser beam 48 a wavelength of 532 nm. The optical system was configured to produce a Gauss-Bessel beam, with a line focus having a length of 0.74 mm and a diameter of 1.2 μm, and an intensity that varied along the length of the line focus. As the sample of the substrate was translated relative to the optical axis of the laser beam, the laser generated repeated bursts of energy throughout the line focus extending at least partially through the thickness of the substrate contiguous with the second primary surface thereof. Each burst included 2 pulses, each pulse having a duration of 7.2 picoseconds, and a duration of 20 nanoseconds separated the 2 pulses. The bursts created damaged portions contiguous with the second primary surface. A non-damaged portion was disposed through the thickness of the substrate between each of the damaged portions and the first primary surface of the substrate.

The intensity of the line focus that each sample of the substrate received to form the series of damaged portions was different. More specifically, the intensity for Sample 1 was 19 μJ, the intensity for Sample 2 was 28 μJ, and the intensity for Sample 3 was 20 μJ. The intensity of the line focus was measured using a high numerical aperture microscope objective and a charge-coupled device (CCD) camera scanning along the optical axis.

In addition, a distance between the first primary surface and a beginning of the line focus was the same for the series of damaged portions formed into Sample 1 and Sample 2. However, the distance was altered for the series of damaged portions formed into Sample 3.

Each of the samples were then etched with an etchant. The etchant was an aqueous bath of 20 vol % HF and 12 vol % HCl. The etchant was maintained at a temperature of 47° C. while etching the samples. No agitation, such as via ultrasound transduction, was applied to the etchant. The bulk etch rate was 0.0046 μm per second to 0.005 μm per second.

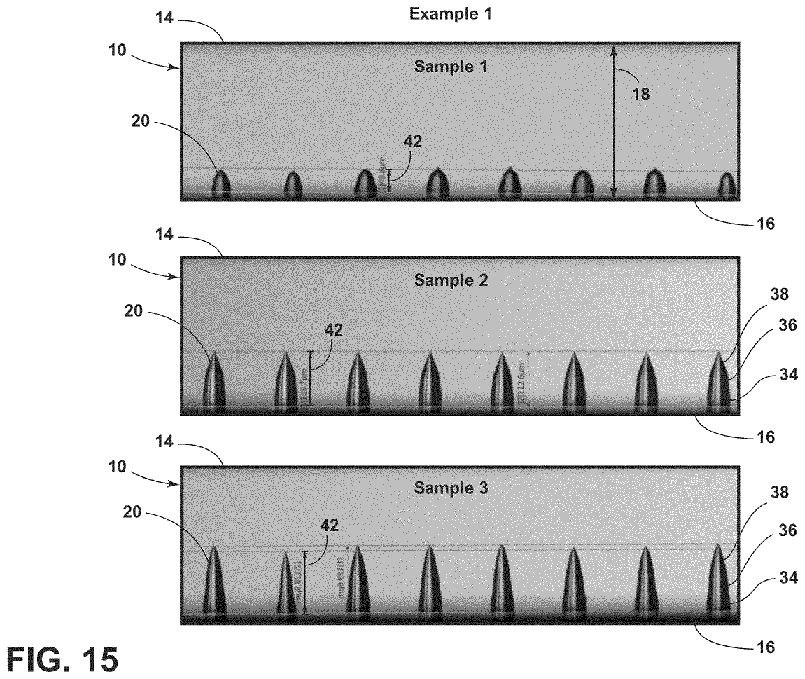

The etching generated blind vias into each of the samples, as depicted at FIG. 15. The blind vias formed into each of the samples had a diameter of about 50 μm. The depth of the blind vias into Sample 1 was about 50 μm. The depth of the blind vias into Sample 2 was about 115 μm. The depth of the blind vias into Sample 3 was about 140 μm. Note that the blind vias for Samples 2 and 3 in particular have a distinct tapered geometry with a first tapered region, a second tapered region, and a third tapered region.

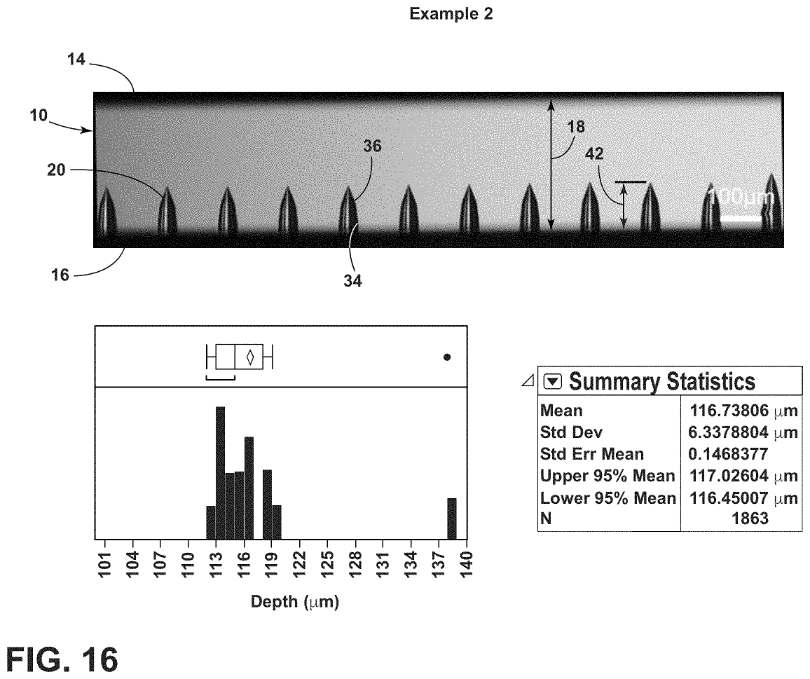

Example 2. For Example 2, another sample of the substrate of Example 1 was selected. The same laser conditions for Sample 2 of Example 1 were utilized to form a series of damaged portions contiguous with the second primary surface of the substrate. The sample was etched in the same manner as the samples of Example 1. Sixteen blind vias contiguous with the second primary surface were thus formed. Twelve of the blind vias are depicted at FIG. 16. The depths of each of the blind vias was measured. A graph of the measurements is additionally reproduced at FIG. 16. The higher the column, the greater the number of blind vias that had a depth within that particular segment of the range on the x-axis. The mean depth, excluding the outlier on the far right having a depth of about 138 μm, was 116.7 μm. The range of depths, excluding the outlier, was about 8 μm. This shows acceptable uniformity in the depths of the blind vias. The diameter of the blind vias was again about 50 μm.

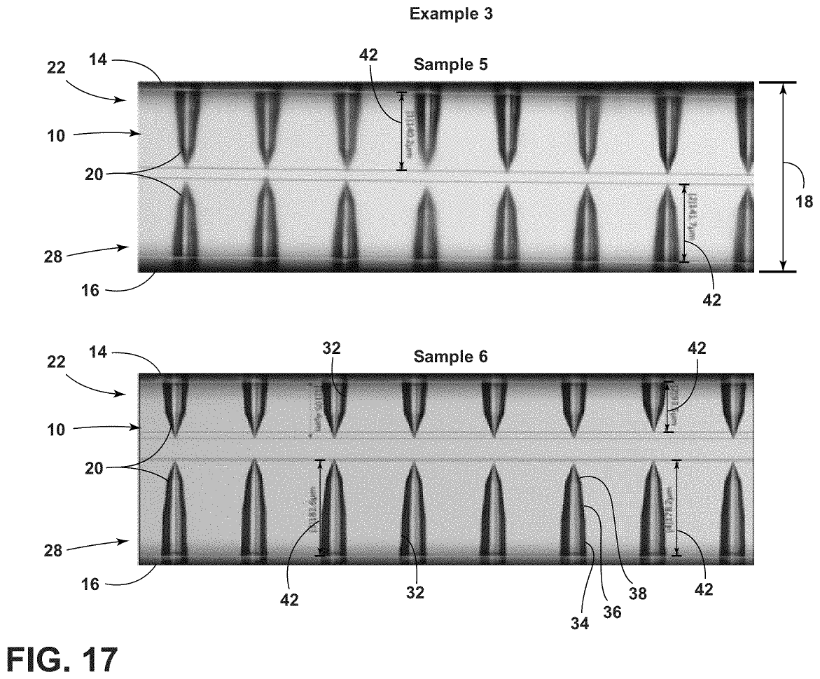

Example 3. For Example 3, two samples (i.e., Sample 5 and Sample 6) of the substrate of Example 1 were selected. The laser of Example 1 using the same setting generated a line focus fully encompassing the thickness of the substrate. The line focus formed a series of first damaged portions and a series of second damaged portions into each of the samples, with non-damaged portions being disposed between pairs of the first damaged portions and the second damaged portions. The distance between the first primary surface and the beginning of the line focus for Sample 6 was altered relative to the distance for Sample 5. The intensity of the line focus for both samples was the same. The samples were then etched thus producing the blind vias into each sample as depicted at FIG. 17.

The depths of the blind vias for both samples were measured and a mean depth calculated. For Sample 5, the mean depth of the blind vias open to the first primary surface of the substrate was about 140 μm, and the mean depth of the blind vias open to the second primary surface was about 142 μm. Sample 5 thus illustrates that blind vias can be formed open to the first primary surface of the substrate that are symmetrical (or at least very close to symmetrical) to the blind vias formed open to the second primary surface of the substrate. Further, Sample 5 illustrates that the blind vias open to either the first primary surface or the second primary surface can have approximately uniform depth. In addition, the geometry of the blind vias has identifiable tapered regions.

Regarding Sample 6, the depths of the blind vias open to the first primary surface ranged from 94 μm to 105 μm, which is an acceptable tolerance. The depths of the blind vias open to the second primary surface ranged from 178 μm to 182 μm, which is also an acceptable tolerance. Sample 6 versus Sample 5 demonstrates that the depth of the blind vias open to the first primary surface and the depth of the blind vias open to the second primary surface can be simultaneously controlled through controlling the distance of the first primary surface to the beginning of the line focus.

Example 4. For Example 4, three additional samples of the substrate of Example 1 were selected, namely Samples 7, 8, and 9. The laser of Example 1 using the same settings generated a line focus fully encompassing the thickness of the substrate. The line focus formed a series of first damaged portions and a series of second damaged portions into each of the samples, with non-damaged portions being disposed between pairs of the first damaged portions and the second damaged portions. The intensity of the line focus was sequentially increased for each sample. That is, the intensity of the line focus used to form the first damaged portions and the second damaged portions of Sample 9 was greater than the intensity of the line focus used for Sample 8, which intensity, in turn, was greater than the intensity of the line focus used for Sample 7. The samples were then etched in the same manner as the samples of Example 1.

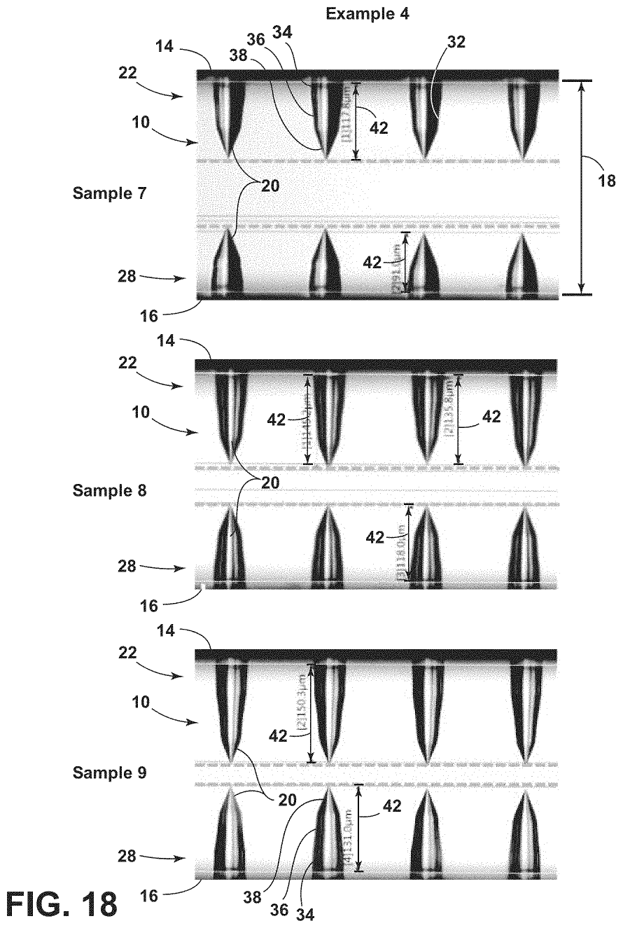

The blind vias formed into each of Samples 7, 8, and 9 are depicted at FIG. 18. As the depiction illustrates, the depths of both the blind vias open to the first primary surface and the second primary surface increased as the intensity of the line focus increased.

In addition, the depths of both the blind vias open to the first primary surface and the second primary surface were relatively consistent for each of the samples. More specifically, for Sample 7, the depths were about 117 μm and 91 μm for the blind vias open to the first primary surface and the through vias open to the second primary surface, respectively. For Sample 8, the depths ranged from 136 μm to 145 μm for the blind vias open to the first primary surface, and was about 118 μm for the blind vias open to the second primary surface. For Sample 9, the depths were about 150 μm and 131 μm for the blind vias open to the first primary surface and the blind vias open to the second primary surface, respectively. No intolerable deviations in depth are illustrated for any of the blind vias.

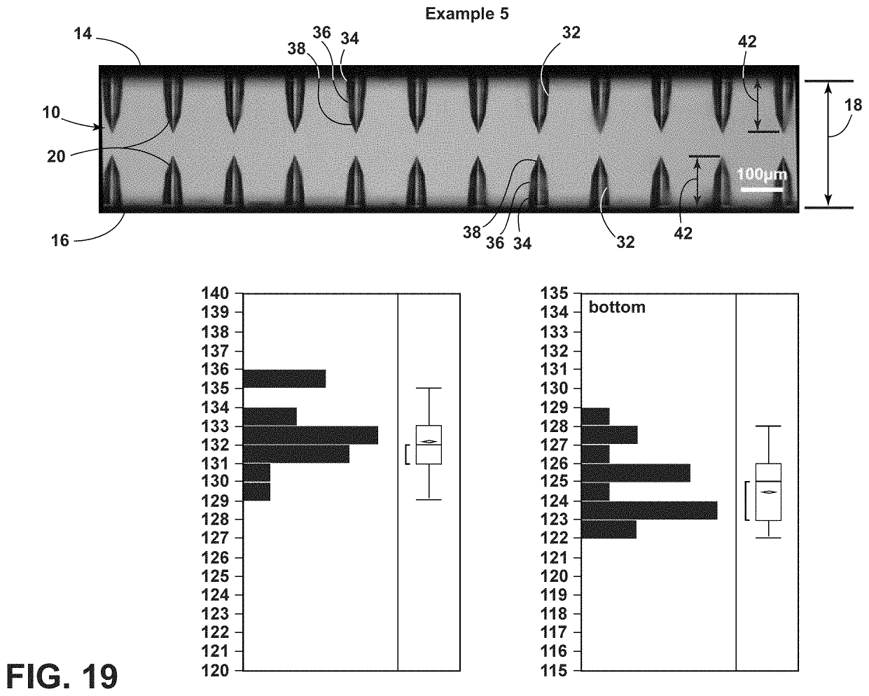

Example 5. For Example 5, one sample of the substrate of Example 1 was selected. The laser of Example 1 using the same settings generated a line focus fully encompassing the thickness of the substrate. The line focus formed a series of first damaged portions and a series of second damaged portions into the sample, with non-damaged portions being disposed between pairs of the first damaged portions and the second damaged portions. The sample was then etched in the same manner as the samples of Example 1. The resulting blind vias are depicted at FIG. 19.

The depths of the blind vias open to the first primary surface (the “top”) fell within a range of 129 μm to 136 μm. The mean depth was calculated to be 132 μm. The standard deviation was 1.7 μm.

The depths of the blind vias open to the second primary surface (the “bottom”) fell within a range of 122 μm to 129 μm. The mean depth was calculated to be 124 μm. The standard deviation was 1.8 μm. These standard deviations are well within acceptable tolerances and reveal a high degree of uniformity.

What is claimed is:

1. A method of forming blind vias in substrates comprising:
(a) transmitting a line focus of a laser beam having a wavelength through a primary surface of a first substrate and into a thickness of the first substrate, the first substrate being transparent to the wavelength of the laser beam, and the line focus having an intensity as a function of depth into the thickness of the first substrate, and the intensity is (i) sufficient to damage the substrate throughout a damaged portion into the thickness of the first substrate contiguous with the primary surface of the first substrate, and (ii) insufficient to damage the first substrate throughout a non-damaged portion that is disposed between the damaged portion and another primary surface of the first substrate.

2. The method of claim 1 further comprising:
(b) repeating (a) to form a series of damaged portions into the thickness of the first substrate contiguous with the primary surface.

3. The method of claim 2 further comprising:
contacting the series of damaged portions of the first substrate with an etchant, thus forming a series of blind vias into the thickness of the first substrate that is open to the primary surface;
wherein, each blind via of the series of the blind vias into the first substrate has a depth, the series of blind vias into the first substrate has a mean depth, and the depths of the series of blind vias into the first substrate deviate from the mean depth by less than +/−10%.

4. The method of claim 3, further comprising:
depositing metal within the series of blind vias of the first substrate.

5. The method of claim 2 further comprising:
(c) repeating steps (a) and (b) with a second substrate and either (i) the intensity of the line focus being altered compared to the first substrate, or (ii) a distance between the other primary surface of the second substrate and a beginning of the line focus along the optical axis of the line focus being altered compared to the first substrate; and
contacting the series of damaged portions of the first substrate and the second substrate with an etchant, thus forming a series of blind vias into the thickness of the first substrate and the second substrate that are open to the primary surface;
wherein, each blind via of the series of the blind vias into the first substrate has a depth, the series of blind vias into the first substrate has a mean depth, and the depths of the series of blind vias into the first substrate deviate from the mean depth by less than +/−10%;
wherein, each blind via of the series of the blind vias into the second substrate has a depth, the series of blind vias into the second substrate has a mean depth, and the depths of the series of blind vias into the second substrate deviate from the mean depth by less than +/−10%; and
wherein, the mean depth of the series of blind vias formed into the first substrate is different than the mean depth of the series of blind vias formed into the second substrate.

6. The method of claim 5, wherein
step (c) comprises repeating steps (a) and (b) with the second substrate and the intensity of the line focus being altered compared to the first substrate.

7. The method of claim 5, wherein
step (c) comprises repeating steps (a) and (b) with the second substrate and the distance between the other primary surface of the second substrate and the beginning of the line focus along the optical axis of the line focus being altered compared to the first substrate.

8. The method of claim 1, wherein
the intensity of the line focus is substantially uniform along the optical axis.

9. The method of claim 1, wherein
the intensity of the line focus is not substantially uniform along the optical axis and varies as a function of position within the thickness of the substrate.

10. The method of claim 1, wherein
the first substrate comprises glass;
a picosecond laser produces the laser beam in a burst of pulses; and
one burst of less than 5 pulses generates the damaged portion.

11. A method of forming blind vias comprising:
(a) transmitting a line focus of a laser beam having a wavelength into the entirety of a thickness of a substrate that is transparent to the wavelength of the laser beam, the line focus having an intensity as a function of depth into the thickness of the substrate, and the intensity is (i) sufficient to damage the substrate throughout a first damaged portion into the thickness of the substrate contiguous with a first primary surface of the substrate, (ii) sufficient to damage the substrate throughout a second damaged portion into the thickness of the substrate contiguous with a second primary surface of the substrate, and (iii) insufficient to damage the substrate throughout a non-damaged portion that is disposed between the first damaged portion and the second damaged portion.

12. The method of claim 11 further comprising:
(b) repeating (a) to form a series of first damaged portions into the thickness of the substrate contiguous with the first primary surface, and a series of second damaged portions into the thickness of the substrate contiguous with the second primary surface.

13. The method of claim 12 further comprising:
(c) contacting the series of first damaged portions and the series of second damaged portions of the substrate with an etchant, thus forming (i) a first series of blind vias into the thickness of the substrate and open to the first primary surface and (ii) a second series of blind vias into the thickness of the substrate and open to the second primary surface.

14. The method of claim 13, wherein
each of the blind vias of the first series of blind vias is coaxial with one blind via of the second series of blind vias.

15. The method of claim 13 further comprising:
depositing metal within the first series of blind vias and the second series of blind vias.

16. The method of claim 13, wherein
each blind via of the first series of blind vias and the second series of blind vias has an interior wall, and the interior wall includes a first tapered region and a second tapered region, wherein the first tapered region and the second tapered region have a different slope.

17. The method of claim 13, wherein
each blind via of the first series of blind vias has a depth, the first series of blind vias has a mean depth, and the depths of the first series of blind vias deviate from the mean depth by less than +/−10%; and
each blind via of the second series of blind vias has a depth, the second series of blind vias has a mean depth, and the depths of the second series of blind vias deviate from the mean depth by less than +/−10%.

18. The method of claim 13, wherein
the etchant is an aqueous solution comprising hydrofluoric acid.

19. The method of claim 13 further comprising:
dividing the substrate into an alpha substrate and a beta substrate, with the alpha substrate including the first series of blind vias and the beta substrate including the second series of blind vias.

20. The method of claim 11, wherein
the substrate comprises glass;
a picosecond laser produces the laser beam in a burst of pulses; and
one burst of less than 5 pulses generates one first damaged portion of the series of first damaged portions and one second damaged portion of the series of second damaged portions.

21. The method of claim 11, wherein
the intensity of the line focus is substantially uniform.

22. The method of claim 11, wherein
the intensity of the line focus is substantially uniform throughout a first intensity region that forms the first damaged portion;
the intensity of the line focus is substantially uniform throughout a second intensity region that forms the second damaged portion; and
the intensity of the line focus at the first intensity region is different than the intensity of the line focus at the second intensity region.

23. The method of claim 11, wherein
the intensity of the line focus is not substantially uniform and varies as a function of position within the thickness of the substrate.
